(19) United States
(12) Patent Application Publication
(10) Pub. No.: US 2019/0228917 A1
(43) Pub. Date: Jul. 25, 2019

(54) INORGANIC-ORGANIC HYBRID SOLAR CELL HAVING DURABILITY AND HIGH PERFORMANCE

(71) Applicant: KOREA RESEARCH INSTITUTE OF CHEMICAL TECHNOLOGY, Daejeon (KR)

(72) Inventors: Sang Il SEOK, Daejeon (KR); Sang Hyuk IM, Daejeon (KR); Jun Hong NOH, Daejeon (KR); Jin Hyuck HEO, Busan (KR)

(21) Appl. No.: 16/260,647

(22) Filed: Jan. 29, 2019

Related U.S. Application Data
(62) Division of application No. 14/759,748, filed on Jul. 8, 2015.

(30) Foreign Application Priority Data
Jan. 10, 2013 (KR) 10-2013-0003131
Jan. 10, 2013 (KR) 10-2013-0003136

(51) Int. Cl. H01G 9/20; H01L 51/42; H01L 51/00

(52) U.S. Cl. CPC H01G 9/2059; H01L 51/4226; H01L 51/005; H01L 2031/0344; H01L 2251/301; Y02E 10/549; H01G 9/2018

(57) ABSTRACT

Provided is a solar cell including: a first electrode; an electron transport layer positioned on the first electrode; a light absorber; a hole transport layer; and a second electrode, wherein the light absorber contains a solid-solution of at least two organic-metal halides with a perovskite structure, having different compositions from each other.

### TECHNICAL FIELD

The present invention relates to a solar cell, and more particularly, to a solar cell capable of having excellent efficiency, preventing degradation by moisture, having an excellent aesthetic value, and being mass-produced by a simple process at low cost.

### BACKGROUND ART

In order to solve depletion of fossil energy and earth-environmental problems caused by using fossil energy, research into alternative energy sources such as solar energy, wind energy, and hydro energy that are recyclable and clean has been actively conducted.

Among them, an interest in a solar cell directly converting solar light into electric energy has significantly increased. Here, the solar cell means a cell generating current-voltage using a photovoltaic effect that the cell absorbs light energy from the solar light to generate electrons and holes.

Currently, an n-p diode type single-crystalline silicon (Si) based solar cell having photo energy conversion efficiency higher than 20% may be manufactured and actually used in solar power generation, and there is a solar cell using a compound semiconductor such as gallium arsenide (GaAs) having conversion efficiency higher than that of the n-p diode type single-crystalline silicon (Si) based solar cell. However, since the inorganic semiconductor based solar cells as described above require a very highly purified material for high efficiency, a large amount of energy is consumed in purifying a raw material. In addition, expensive processing equipment is required during a single crystallization process or a thinning process using the raw material, such that there is a limitation in lowering a manufacturing cost of the solar cell, thereby blocking large-scale use of the solar cell.

Therefore, in order to manufacture the solar cell at low cost, cost of a core material used in the solar cell or the manufacturing process of the solar cell should be greatly reduced, and research into a dye-sensitized solar cell (DSSC) and an organic solar cell that may be manufactured using an inexpensive material and process has been actively conducted as an alternative to the inorganic semiconductor based solar cell.

However, in the case of an organic solar cell using a conductive polymer, efficiency is still about 8% (Advanced Materials, 23 (2011) 4636), and in the dye-sensitized solar cell, in the case of using a liquid electrolyte, the maximum efficiency is about 12 to 13% (Science 334, (2011) 629), and in the case of using a solid type hole conductor, efficiency is still low (7 to 8%). Even in the case of an inorganic-organic hybrid solar cell in a form in which inorganic semiconductor nanoparticles and a hole conductive polymer are coupled in a structure of the dye-sensitized solar cell, efficiency thereof is still about 6% (Nano Letters, 11 (2011) 4789).

Therefore, the development of a solar cell capable of having excellent efficiency enough to replace the single-crystalline silicon (Si) based solar cell according to the related art has been urgently demanded. To this end, the development of a solar cell having a wide band gap has been urgently demanded. In addition, at the time of installing a solar cell outside, the solar cell should be installed to a window or an external wall of a building, but there is a limitation in developing a solar cell material capable of implementing various colors up to now, such that application thereof is limited. Therefore, the development of a material capable of being changed into various colors has been urgently demanded. Further, the solar cell should be exposed to the outside, but in the case in which the solar cell is exposed to moisture for a long period of time, an environmental problem that it is impossible to use the solar cell for a long period of time due to performance degradation of the solar cell by moisture, or the like, should be urgently solved.

### DISCLOSURE

### Technical Problem

An object of the present invention is to provide a solar cell having excellent photoelectric conversion efficiency. Another object of the present invention is to provide a solar cell capable of preventing performance degradation even under a humid environment, and a manufacturing method thereof, and provide a solar cell capable of being mass-produced by a significantly simple process at low cost. Another object of the present invention is to provide a novel solar cell capable of implementing various colors.

### Technical Solution

In one general aspect, a solar cell includes a first electrode; an electron transport layer positioned on the first electrode; a light absorber; a hole transport layer; and a second electrode, wherein the light absorber is a composite light absorber containing a solid-solution of at least two organic-metal halides with a perovskite structure, having different compositions from each other.

In the solar cell according to an exemplary embodiment of the present invention, the electron transport layer may be made of an inorganic material and contain a metal oxide. The electron transport layer may be a flat metal oxide layer, a metal oxide layer having surface unevenness, a metal oxide layer having a composite structure in which a homogeneous or heterogeneous metal oxide nanostructure is formed on a surface of a metal oxide layer in a thin film shape, or a porous metal oxide layer. Preferably, the electron transport layer may be a porous metal oxide layer having a porous structure due to metal oxide particles. In this case, as the metal oxide of the electron transport layer, any metal oxide may be used as long as it is used to attach a dye or quantum dot and transport electrons in a general dye-sensitized solar cell or inorganic quantum dot-sensitized solar cell.

More preferably, the solar cell according to the present invention may include a solar cell including: a first electrode; a composite layer formed by filling a light absorber in a porous structure of a porous metal oxide layer (electron transport layer) positioned on the first electrode; a light absorption structure body positioned on the composite layer and made of the light absorber; a hole transport layer positioned on the light absorption structure body; and a second electrode positioned on the hole transport layer.

More preferably, the light absorber fills in pores of the porous metal oxide layer (electron transport layer) and the light absorption structure body having a form of a light absorber thin film or light absorber pillar extended from a porous support layer, or a light absorber pillar protruding from a light absorber thin film is formed, such that an object of the present invention may be more excellently achieved.

According to the present invention, in the case in which among at least two organic-metal halides forming the solid-solution, one organic-metal halide is iodide, and another organic-metal halide is bromide, the solar cell may have excellent durability and high power conversion efficiency, and a color of the solar cell itself may be adjusted, such that the solar cell may have the most excellent properties.

According to the present invention, in the case in which among at least two organic-metal halides forming the solid-solution, one organic-metal halide is iodide, and another organic-metal halide is bromide, or one organic-metal halide is chloride, and another organic-metal halide is bromide, more various colors may be implemented. In detail, the solar cell may have a color variously adjusted by an element ratio between different halogen ions contained in the solid-solution.

According to the present invention, among at least two organic-metal halides forming the solid-solution, one organic-metal halide may satisfy the following Chemical Formula 1, and another organic-metal halide may satisfy the following Chemical Formula 2.

AMX₃ (Chemical Formula 1)

(In Chemical Formula 1, A is a monovalent organic ammonium ion, an ammonium ion, or Cs⁺, M is a divalent metal ion, and X is Br⁻.)

A′M′X′₃ (Chemical Formula 2)

(In Chemical Formula 2, A′ is a monovalent organic ammonium ion, an ammonium ion, or Cs⁺, M′ is a divalent metal ion, and X′ is I⁻ or Cl⁻.)

According to the present invention, the composite light absorber made of the solid-solution of at least two organic-metal halides may be represented by the following Chemical Formula 3, wherein in Chemical Formula 3, A″ is a monovalent organic ammonium ion, an ammonium ion, or Cs⁺, M″ is a divalent metal ion, and X₁ and X₂ are different halogen elements from each other. In view of implementing various colors, X₁—X₂ may be I⁻—Br⁻ or Cl⁻—Br⁻, and in view of implementing various colors and having excellent durability and high photoelectric efficiency, X₁ may be preferably I⁻, X₂ may be preferably Br⁻, m may be a real number satisfying 0<m<1. Further, in order to have power conversion efficiency of 7% or more, it is preferable that m satisfies 0<m≤0.5.

A″M″(X₁₍₁₋ₘ₎X₂₍ₘ₎)₃ (Chemical Formula 3)

According to the present invention, when the solar cell having the above-mentioned configuration is left in a constant temperature and constant humidity state (25° C., RH 55%) for 100 hours, power conversion efficiency of the solar cell may be maintained at 18% or more, preferably 40% or more, and more preferably 80% or more as compared to an initial value (as fabricated).

In addition, according to the present invention, particularly, in the case in which the composite light absorber simultaneously has moisture resistance and excellent power conversion efficiency as compared to a single organic-metal halide (material of Chemical Formula 1 or 2) having a single perovskite structure, in Chemical Formula 3, X₁ may be I⁻, X₂ may be Br⁻, m may satisfy preferably 0<m<0.35, more preferably, 0<m≤0.3, further more preferably, 0.1≤m≤0.3, and most preferably 0.15≤n≤0.3. Within the above-mentioned range, it is possible to entirely overcome a disadvantage that in the case of using the organic-metal halide alone (particularly, an organic-metal bromine based perovskite light absorber), power conversion efficiency is significantly low, such that the organic-metal halide may not be substantially adopted, and a disadvantage that it is impossible to practically use the organic-metal halide (particularly, an organic-metal iodide based perovskite) due to excessively low moisture resistance, such that it is possible to provide a solar cell capable of simultaneously satisfying power conversion efficiency and moisture resistance as compared to the case of using each organic-metal halide alone. In addition, the color is adjusted by an m value, such that a solar cell having an excellent aesthetic value may be manufactured.

In the solar cell according to an exemplary embodiment of the present invention, among at least two organic-metal halides forming the solid-solution, one organic-metal halide may be iodide, and another organic-metal halide may be bromide.

In the solar cell according to an exemplary embodiment of the present invention, when a mole number of all halogen elements contained in the solid-solution is 1 mol, the solid-solution may contain more than 0 mol to less than 1 mol of bromine ion, and in the case of the solar cell particularly having moisture resistance as described above, the solid-solution contains 0.1 mol or more of bromine ion, such that when the solar cell is left in the constant temperature and constant humidity state (25° C., RH 55%) for 100 hours, power conversion efficiency may be maintained at 40% or more compared to an initial value (as fabricated). More preferably, the solid-solution contains 0.15 mol or more of the bromine ion, such that when the solar cell is left in the constant temperature and constant humidity state (25° C., RH 55%) for 100 hours, power conversion efficiency may be maintained at 80% or more as compared to the initial value (as fabricated). In view of moisture resistance, it is most preferable that the solid-solution contains 0.2 mol or more of the bromine ion, such that when the solar cell is left in the constant temperature and constant humidity state (25° C., RH 55%) for 100 hours, power conversion efficiency may be maintained at the initial value (as fabricated) or to be close to the initial value. In order to manufacture a solar cell having power conversion efficiency larger than that of a reference solar cell containing one organic-metal halide among at least two organic-metal halides forming the solid-solution as the light absorber, when the mole number of all halogen elements contained in the solid-solution is 1 mol, the solid-solution may contain more than 0 mol to less than 0.35 mol, more preferably, more than 0 mol to 0.3 mol or less of bromine ion. In this case, the solar cell may have significantly excellent power conversion efficiency as compared to the reference solar cell. When considering both of the moisture resistance and the power conversion efficiency, m may satisfy 0.1≤m<0.35, preferably 0.15≤m<0.35. Particularly, m may satisfy more preferably 0.2≤m<0.35, most preferably 0.2≤m≤0.3 so that when the solar cell is left in the constant temperature and constant humidity state (25° C., RH 55%) for 100 hours, power conversion efficiency may be maintained at the initial value (as fabricated) or to be close to the initial value, and the solar cell may have power conversion efficiency larger than that of the reference solar cell containing one organic-metal halide among at least two organic-metal halides forming the solid-solution as the light absorber. However, in the case of mainly considering power conversion efficiency improvement rather than moisture resistance depending on use environment and conditions of the solar cell, m satisfies 0.01≤m<0.35, such that the solar cell may have power conversion efficiency larger than that of the reference solar cell containing one organic-metal halide (as an example, organic-metal bromide or organic-metal iodide) among at least two organic-metal halides forming the solid-solution as the light absorber.

In the solar cell according to an exemplary embodiment of the present invention, among at least two organic-metal halides forming the solid-solution, one organic-metal halide may satisfy the following Chemical Formula 1, and another organic-metal halide may satisfy the following Chemical Formula 2.

AMX₃ (Chemical Formula 1)

In Chemical Formula 1, A is a monovalent organic ammonium ion, a monovalent ammonium ion, or Cs⁺, M is a divalent metal ion, and X is Br⁻.

A′M′X′₃ (Chemical Formula 2)

In Chemical Formula 2, A′ is a monovalent organic ammonium ion, a monovalent ammonium ion, or Cs⁺, M′ is a divalent metal ion, and X′ is I⁻ or Cl⁻.

In the solar cell according to the exemplary embodiment of the present invention, the solid-solution may satisfy the following Chemical Formula 3.

A″M″(X₁₍₁₋ₘ₎X₂₍ₘ₎)₃ (Chemical Formula 3)

In Chemical Formula 3, A″ is a monovalent organic ammonium ion, a monovalent ammonium ion, or Cs⁺, M″ is a divalent metal ion, and X₁ is I⁻ or Cl⁻ and X₂ is Br—. In order to provide a solar cell having moisture resistance, m is a real number satisfying 0<m<1, preferably, 0.1≤m≤0.9, more preferably 0.15≤m≤0.9, and further more preferably, 0.2≤m≤0.9, and in order to have high efficiency, when m is a real number satisfying 0<m<0.35, more preferably 0.01≤m≤0.3, power conversion efficiency may be further improved, such that the solar cell may have excellent effect as compared to each of the reference solar cells.

The solar cell according to the present invention may include the first electrode; the composite layer positioned on the first electrode and including the light absorber impregnated thereinto; the light absorption structure body positioned on the composite layer and composed of the light absorber; the hole transport layer positioned on the light absorption structure body; and the second electrode positioned on the hole transport layer.

The present invention includes all contents disclosed in PCT/KR2013/008270 and PCT/KR2013/008268 by the present applicant. Since the composite layer, a content of the light absorber filled in the composite layer, or a structure of the light absorption structure body, and a detailed manufacturing method thereof were disclosed in PCT/KR2013/008270 and PCT/KR2013/008268 applied earlier by the present inventor, a description may refer to the prior applications.

In the solar cell according to an exemplary embodiment of the present invention, when the light absorption structure body has a form of a light absorber thin film or a light absorber pillar extended from the porous support layer of which pores are filled with the light absorber, or a light absorber pillar protruding from the light absorber thin film, the solar cell having more excellent light efficiency and excellent moisture resistance may be manufactured.

### Advantageous Effects

A solar cell according to the present invention may have excellent photoelectric conversion efficiency, and degradation by moisture may be prevented, such that even though the solar cell is exposed to a high humidity environment, the solar cell may be stably used for a long period of time. In the solar cell according to an exemplary embodiment of the present invention, power conversion efficiency of the solar cell may be 11.0% or more.

Further, the solar cell according to the present invention may have significantly excellent power conversion efficiency, and as the light absorber in a solid-solution phase is formed by a simple solution process, a solar cell having significantly high efficiency may be mass-produced in a short time by a significantly easy, simple, and cheap process.

### DESCRIPTION OF DRAWINGS

FIG. 1 is a scanning electron microscope (SEM) photograph of a surface after forming a light absorber of Example 4;

FIG. 2 is a scanning electron microscope (SEM) photograph of a surface after forming a light absorber according to Example 2 of the present invention;

FIG. 3 is an optical photograph of a substrate provided with a CH₃NH₃Pb(I₁₋ₘBrₘ)₃ light absorber formed in a TiO₂ porous support layer on an FTO substrate;

FIG. 4 is a view illustrating a measurement result of UV-VIS absorbance spectrum depending on m of the CH₃NH₃Pb(I₁₋ₘBrₘ)₃ light absorber formed in the TiO₂ porous support layer on the FTO substrate;

FIG. 5 is a view illustrating a measurement result of UV-VIS absorbance spectrum depending on l-m of a CH₃NH₃Pb(Cl₁₋ₘBrₘ)₃ light active layer (light absorbing layer) formed in a TiO₂ porous support layer on an FTO substrate;

FIG. 6 is a view illustrating a measurement result of UV-VIS absorbance spectrum depending on m of a CH₃NH₃Pb(I₁₋ₘClₘ)₃ light active layer formed in a TiO₂ porous support layer on an FTO substrate; and

FIGS. 7A and 7B are scanning electron microscope photographs of a light absorption structure body of a light absorber film manufactured in Example.

### BEST MODE

A solar cell according to an exemplary embodiment of the present invention is characterized in that the solar cell contains a solid-solution of at least two organic-metal halides with a perovskite structure, having different compositions from each other as a light absorber.

The solar cell may have larger power conversion efficiency than that of a reference solar cell containing one organic-metal halide of at least two organic-metal halides forming the light absorber solid-solution according to an exemplary embodiment of the present invention as a light absorber, and when the solar cell is left in a constant temperature and constant humidity state (25° C., RH 55%) for 100 hours, power conversion efficiency may be maintained at 18% or more as compared to an initial value. Preferably, the solar cell according to an exemplary embodiment of the present invention contains the solid-solution of at least two organic-metal halides with the perovskite structure, having different compositions from each other as the light absorber, and when the solar cell is left in the constant temperature and constant humidity state (25° C., RH 55%) for 100 hours, power conversion efficiency may be maintained at 40% or more as compared to the initial value. More preferably, the solar cell according to an exemplary embodiment of the present invention contains the solid-solution of at least two organic-metal halides with the perovskite structure, having different compositions from each other as the light absorber, and when the solar cell is left in the constant temperature and constant humidity state (25° C., RH 55%) for 100 hours, power conversion efficiency may be maintained at 80% or more as compared to the initial value.

In detail, the solar cell according to an exemplary embodiment of the present invention contains a solid-solution in which at least two organic-metal halides with the perovskite structure (inorganic/organic hybrid perovskite compounds), having different compositions from each other forms a solid-solution phase as the light absorber, such that the reason is not clearly known but degradation by moisture may be prevented. In addition, the solar cell adopts the solid-solution of at least two organic-metal halides with the perovskite structure, such that the solar cell has more excellent power conversion efficiency as compared to the reference solar cell adopting one organic-metal halide. Further, the solar cell adopts the solid-solution of at least two organic-metal halides with the perovskite structure, such that it is possible to adjust a color of the solar cell itself, thereby making it possible to have an excellent commercial value.

Due to a property of preventing degradation by moisture and more improved power conversion efficiency, even though the solar cell is exposed to a high humidity environment depending on climate change, degradation of the solar cell may be prevented and performance of the solar cell may be stably exhibited for a long period of time, such that the solar cell may be stably used for a long period of time. Therefore, these properties are very important properties at the time of commercializing the solar cell, but research thereinto has been hardly conducted except for the present invention. Further, at the time of utilizing the solar cell in an exterior of a building, in the case in which various colors are implemented in the solar cell itself, an aesthetic value may be increased, such that commercialization of the solar cell may be promoted.

In describing the present invention in detail, the initial value, which is power conversion efficiency immediately after the solar cell is manufactured, means power conversion efficiency measured in a state in which the solar cell is not intentionally exposed to moisture immediately after the solar cell is manufactured.

In describing the present invention in detail, power conversion efficiency may be 4.8% or more, and particularly, excellent power conversion efficiency may be 11% or more. This efficiency of the solar cell is power conversion efficiency measured in the case in which light corresponding to solar spectrum is incident at an intensity of 100 mW/cm², more specifically, power conversion efficiency measured using an Oriel class A solar simulator (Newport, model 91195A) under AM 1.5 condition.

In the solar cell according to an exemplary embodiment of the present invention, at least two organic-metal halides forming the solid-solution contain different halogen ions from each other. More specifically, each of the organic-metal halides may contain one kind of halogen ion different from each other. Therefore, the solid-solution may contain at least two kinds of halogen ions.

In more detail, among at least two organic-metal halides forming the solid-solution, one organic-metal halide may be iodide, another organic-metal halide may be bromide, and the solid-solution may contain bromine and iodine.

In more detail, among at least two organic-metal halides forming the solid-solution, one organic-metal halide may be chloride, another organic-metal halide may be bromide, and the solid-solution may contain chlorine and bromine.

In the solar cell according to an exemplary embodiment of the present invention, in more detail, when a mole number of all halogen elements contained in the solid-solution is 1 mol, the solid-solution may contain more than 0 mol to less than 1 mol of bromine ion.

In the solar cell having moisture resistance in the present invention, when the mole number of all halogen elements contained in the solid-solution is 1 mol, the solid-solution may contain more than 0 mol to less than 1 mol, preferably 0.1 mol or more to 0.9 mol or less, and more preferably 0.15 mol or more to 0.9 mol or less of bromine ion. Further, in the case of a solar cell having power conversion efficiency of 7% or more and improved moisture resistance, when the mole number of all halogen elements contained in the solid-solution is 1 mol, the solid-solution may contain preferably 0.1 mol or more to 0.5 mol or less, more preferably 0.15 mol or more to 0.5 mol or less of bromine ion. When the mole number of all halogen elements contained in the solid-solution is 1 mol, in the case in which the solid-solution contains more than 0 mol to less than 0.35 mol of bromine ion, the solar cell may have further increased power conversion efficiency as compared to a reference solar cell having the same structure, having organic-metal iodide or organic-metal bromide as the light absorber. More preferably, when the mole number of all halogen elements contained in the solid-solution is 1 mol, in the case in which the solid-solution contains 0.1 mol or more to less than 0.35 mol, preferably, 0.15 mol or more to less than 0.35 mol, and more preferably 0.2 mol or more to less than 0.35 mol of bromine ion, power conversion efficiency may be increased and moisture resistance may be achieved.

As described above, the solid-solution may contain at least two halogen ions, and a light absorption wavelength and/or band gap energy may be controlled by an element ratio between at least two halogen ions forming the solid-solution. Here, the light absorption wavelength may be a wavelength corresponding to an X-axis intercept obtained by virtually extending a linear line in a region in which the light absorber starts to absorb light and absorbance is linearly increased on a wavelength-dependent absorbance spectrum obtained by assigning a wavelength of the irradiated light to an X-axis and assigning absorbance of the light absorber to a y-axis when light having a wavelength of 300 nm to 1200 nm is irradiated on the solar cell.

In detail, among at least two organic-metal halides forming the solid-solution, one organic-metal halide may contain halogen ion such as I⁻ or Cl⁻ and another organic-metal halide may contain halogen ion such as Br⁻. Therefore, the different halogen ions contained in the solid-solution may be I⁻ and Br⁻ or Cl⁻ and Br⁻.

In more detail, the light absorption wavelength and/or the band gap energy of the solid-solution may be controlled by an element ratio between the halogen ions (I⁻ and Br⁻ or Cl⁻ and Br⁻) contained in the solid-solution, that is, an element ratio of I⁻ and Br⁻ or an element ratio of Cl⁻ and Br⁻.

In the solar cell according to an exemplary embodiment of the present invention, the light absorption wavelength λ₁(ss) of the solid-solution may satisfy 530 nm<λ₁(ss)<800 nm. As described above, the solid-solution may be a solid-solution phase of at least two organic-metal halides containing different compositions, more specifically, different halogen ions. In this case, the light absorption wavelength of the solid-solution may be controlled by the element ratio between at least two halogen ions forming the solid-solution. That is, the light absorption wavelength of the solid-solution may be controlled by a molar ratio between at least two organic-metal halides forming the solid-solution.

In detail, the light absorption wavelength λ₁(ss) of the solid-solution may satisfy 530 nm<λ₁(ss)<800 nm, and two different halogen ions contained in the solid-solution may be I⁻ and Br⁻. In more detail, the solid-solution may have a light absorption wavelength of 540 nm to 790 nm, and when the mole number of all halogen elements contained in the solid-solution is 1 mol, the solid-solution may contain 0.01 mol or more to 0.99 mol or less of bromine ion.

In the solar cell according to an exemplary embodiment of the present invention, a light absorption wavelength λ₂(ss) of the solid-solution may satisfy 400 nm<λ₂(ss)<530 nm, and two different halogen ions contained in the solid-solution may be CI⁻ and Br⁻. The solid-solution may have a light absorption wavelength of 410 nm to 520 nm, and when the mole number of all halogen elements contained in the solid-solution is 1 mol, the solid-solution may contain 0.01 mol or more to 0.99 mol or less of bromine ion.

The absorption wavelength as described above is in a range in which the solid-solution may be easily distinguished by the naked eyes and have a color satisfying aesthetic requirements such as an orange or yellow color.

In describing the light absorber provided in the solar cell according to an exemplary embodiment of the present invention in detail, properties of the light absorber are described based on the light absorption wavelength as described above, but since the light absorption wavelength λ and the band gap energy Eg have Correlation Equation Eg=1240/λ, the band gap energy of the light absorber may be calculated from the above-mentioned light absorption wavelength.

In the solar cell according to an exemplary embodiment of the present invention, among at least two organic-metal halides forming the solid-solution, one organic-metal halide may satisfy the following Chemical Formula 1.

AMX₃ (Chemical Formula 1)

(In Chemical Formula 1, A is a monovalent organic ammonium ion, a monovalent ammonium ion, or Cs⁺, M is a divalent metal ion, and X is Br⁻.)

More specifically, in Chemical Formula 1, M may be one or at least two metal ions selected from Cu²⁺, Ni²⁺, Co²⁺, Fe²⁺, Mn²⁺, Cr²⁺, Pd²⁺, Cd²⁺, Ge²⁺, Pb²⁺, and Yb²⁺.

In the solar cell according to an exemplary embodiment of the present invention, among at least two organic-metal halides forming the solid-solution, another organic-metal halide may satisfy the following Chemical Formula 2.

A′M′X₃ (Chemical Formula 2)

In Chemical Formula 2, A′ is a monovalent organic ammonium ion, a monovalent ammonium ion, or Cs⁺, M′ is a divalent metal ion, and X′ is I⁻ or Cl⁻.

Substantially, in Chemical Formula 2, A′ may be the same as A of Chemical Formula 1.

More specifically, in Chemical Formula 2, M′ may be one or at least two metal ions selected from Cu²⁺, Ni²⁺, Co²⁺, Fe²⁺, Mn²⁺, Cr²⁺, Pd²⁺, Cd²⁺, Ge²⁺, Sn²⁺, Pb²⁺, and Yb²⁺, independently of M of Chemical Formula 1. Substantially, in Chemical Formula 2, M′ may be the same as M of Chemical Formula 1.

In detail, one organic-metal halide forming the solid-solution may satisfy the following Chemical Formula 1-1, and another organic-metal halide may satisfy the following Chemical Formula 2-1.

(R₁—NH₃⁺)MX₃ (Chemical Formula 1-1)

In Chemical Formula 1-1, R₁ is (C1-C24)alkyl, (C3-C20)cycloalkyl, or (C6-C20)aryl, M is one or at least two metal ions selected from Cu²⁺, Ni²⁺, Fe²⁺, Mn²⁺, Cr²⁺, Pd²⁺, Cd²⁺, Ge²⁺, Sn²⁺, Pb²⁺, and Yb²⁺, and X is Br⁻. In more detail, in Chemical Formula 1-1, R₁ may be (C1-C24)alkyl, more specifically, (C1-C7)alkyl. (C1-C7) alkyl may be preferable in view that the light absorber may be easily formed in fine pores of the porous metal oxide layer.

(R₁′—NH₃⁺)M′X′₃ (Chemical Formula 2-1)

In Chemical Formula 2-1, R₁′ is the same as R₁ of Chemical Formula 1-1, M′ is the same as M of Chemical Formula 1-1, and X′ is I⁻ or Cl⁻.

In detail, one organic-metal halide forming the solid-solution may satisfy the following Chemical Formula 1-2, and another organic-metal halide may satisfy the following Chemical Formula 2-2.

(R₂—C₃H₃N₂⁺—R₃)MX₃ (Chemical Formula 1-2)

In Chemical Formula 1-2, R₂ is (C1-C24)alkyl, (C3-C20)cycloalkyl, or (C6-C20)aryl, R₃ is hydrogen or (C1-C24)alkyl, M is one or at least two metal ions selected from Cu²⁺, Ni²⁺, Co²⁺, Cr²⁺, Pd²⁺, Cd²⁺, Ge²⁺, Sn²⁺, Pb²⁺, and Yb²⁺, and X is Br⁻. R₂ may be (C1-C24)alkyl, specifically, (C1-C7)alkyl, and R₃ may be hydrogen or (C1-C7)alkyl, which is preferable in view that the light absorber may be easily formed in fine pores of the porous metal oxide layer.

(R₂′—C₃H₃N₂⁺—R₃′)M′X′₃ (Chemical Formula 2-2)

In Chemical Formula 2-2, R₂′ is the same as R₂ of Chemical Formula 1-2, R₃′ is the same as R₃ of Chemical Formula 1-2, M′ is the same as M of Chemical Formula 1-2, and X′ is I⁻ or Cl⁻.

As in the solid-solution according to an exemplary embodiment of the present invention, the perovskite structure is maintained and the organic-metal halides having different compositions as those in Chemical Formulas 1 and 2 form a solid-solution phase and a single crystalline phase, M(M′) is positioned at the center of the unit cell in the perovskite structure and X(X′) is positioned at the center of each face of the unit cell to form an octahedron structure based on M(M′), and A(A′) may be positioned at each corner of the unit cell.

In this case, when A or A′ is a monovalent ammonium ion, one organic-metal halide forming the solid-solution may be NH₄MX₃, similarly to Chemical Formula 1-1, wherein M and X are as defined in Chemical Formula 1-1. Further, when A or A′ is a monovalent ammonium ion, another organic-metal halide forming the solid-solution may be NH₄M′X′₃, similarly to Chemical Formula 2-1, wherein M′ and X′ are as defined in Chemical Formula 2-1.

In the solar cell according to the exemplary embodiment of the present invention, the solid-solution may satisfy the following Chemical Formula 3.

A″M″(X₁₍₁₋ₘ₎X₂₍ₘ₎)₃ (Chemical Formula 3)

In Chemical Formula 3, A″ is a monovalent organic ammonium ion, a monovalent ammonium ion, or Cs⁺, M″ is a divalent metal ion, X₁ is I⁻ or Cl⁻, and X₂ is Br⁻.

In Chemical Formula 3, m satisfies 0<m<1, and particularly, X₁ is I⁻, X₂ is Br⁻, and m is a real number satisfying preferably 0.1≤m≤0.9, more preferably 0.15≤m≤0.9, and most preferably 0.2≤m≤0.9 for the solar cell having excellent moisture resistance. In Chemical Formula 3, m satisfies the above-mentioned numerical range, such that when the solar cell is left in the constant temperature and constant humidity state (25° C., RH 55%) for 100 hours, power conversion efficiency may be maintained at preferably 40% or more, and more preferably 80% or more. More preferably, a decrease in power conversion efficiency may be substantially prevented. In order to allow the solar cell to have high power conversion efficiency of 7% or more and excellent moisture resistance, X₁ is I⁻, X₂ is Br⁻, and m is a real number satisfying preferably 0.1≤m≤0.5, more preferably 0.15≤m≤0.5, and most preferably 0.2≤m≤0.5.

In order to allow the solar cell to have more excellent power conversion efficiency as compared to the case of using a single organic-metal halide with a perovskite structure of Chemical Formula 1 or 2 as the light absorber while having excellent moisture resistance, X₁ is I⁻, X₂ is Br⁻, and m may satisfy preferably 0.1≤m<0.35, more preferably 0.15≤m<0.35.

Further, when at least two organic-metal halides forming the solid-solution have a structure of Chemical Formula 3, the solar cell may have excellent power conversion efficiency as compared to the reference solar cells having a single organic-metal halide. Particularly, in order to allow the solar cell to simultaneously have power conversion efficiency higher than that of the reference solar cell, a significantly high power conversion efficiency value, and excellent moisture resistance, m satisfies preferably 0.1≤m≤0.3, more preferably, 0.15≤m≤0.3. In this case, the solar cell may have significantly high power conversion efficiency of 11% or more.

When the light absorption wavelength is changed, a color exhibited by the solar cell may be changed, but X₁ is I⁻, X₂ is Br⁻, and m is a real number satisfying preferably 0.01≤m≤0.99, such that the solid-solution may have a light absorption wavelength of 540 nm to 790 nm. Independently, X₁ is CI⁻, X₂ is Br⁻, and m is a real number satisfying preferably 0.01≤m≤0.99, such that the solid-solution may have a light absorption wavelength of 410 nm to 520 nm. The light absorption wavelength as described above is in a range in which the solar cell may have a color satisfying aesthetic requirements such as an orange or yellow color.

In the case in which A″ is a monovalent ammonium ion, the solid-solution may be NH₄M″(X₁₍₁₋ₘ₎X₂₍ₘ₎)₃, similarly to Chemical Formula 3, wherein M″, X₁, and X₂ are as defined in Chemical Formula 3.

In the case in which A″ is a monovalent organic ammonium ion, the solid-solution may satisfy the following Chemical Formula 3-1.

(R₁″—NH₃)M″(X₁₍₁₋ₘ₎X₂₍ₘ₎)₃ (Chemical Formula 3-1)

In Chemical Formula 3-1, R₁″ is (C1-C24)alkyl, (C3-C20)cycloalkyl, or (C6-C20)aryl, M″ is one or two or more metal ions selected from Cu²⁺, Ni²⁺, Co²⁺, Fe²⁺, Mn²⁺, Cr²⁺, Pd²⁺, Cd²⁺, Ge²⁺, Sn²⁺, Pb²⁺, and Yb²⁺, and X₁ is l- or CI⁻, X₂ is Br⁻, and m is as defined above.

In the case in which A″ is a monovalent organic ammonium ion, the solid-solution may satisfy the following Chemical Formula 3-2.

(R₂″—C₃H₃N₂—R₃″)M″(X₁₍₁₋ₘ₎X₂₍ₘ₎)₃ (Chemical Formula 3-2)

In Chemical Formula 3-2, R₂″ is (C1-C24)alkyl, (C3-C20)cycloalkyl, or (C6-C20)aryl, R₃″ is hydrogen or (C1-C24)alkyl, M″ is one or two or more metal ions selected from Cu²⁺, Ni²⁺, Co²⁺, Fe²⁺, Mn²⁺, Cr²⁺, Pd²⁺, Cd²⁺, Ge²⁺, Sn²⁺, Pb²⁺, and Yb²⁺, and X₁ is l⁻ or CI⁻, X₂ is Br⁻, and m is as defined above.

As described above, the solar cell according to an exemplary embodiment of the present invention contains the solid-solution in which at least two organic-metal halides with the perovskite structure, having different compositions from each other, form the solid-solution phase as the light absorber, such that the solar cell may have significantly excellent water stability and excellent power conversion efficiency and satisfy a commercially required aesthetic value.

The solar cell according to the present invention includes a solar cell containing the above-mentioned solid-solution phase as the light absorber.

In detail, the solar cell according to an exemplary embodiment of the present invention is a solar cell including a first electrode; an electron transport layer positioned on the first electrode; a light absorber; a hole transport layer; and a second electrode, wherein the light absorber may contain the solid-solution of at least two organic-metal halides with a perovskite structure, having different compositions from each other as the light absorber.

In the solar cell according to an exemplary embodiment of the present invention, the electron transport layer may be made of an inorganic material and contain a metal oxide. The electron transport layer may be a flat metal oxide layer, a metal oxide layer having surface unevenness, a metal oxide layer having a composite structure in which a homogeneous or heterogeneous metal oxide nanostructure (including a metal oxide nanowire and/or nanotube) is formed on a surface of a metal oxide layer in a thin film shape, or a porous metal oxide layer. Preferably, the electron transport layer may be a porous metal oxide layer having a porous structure due to metal oxide particles. The metal oxide layer having surface unevenness may include uneven portions formed on a surface of the metal oxide layer by physical force such as artificial scraping and include uneven portions formed on the surface of the metal oxide layer by thermal and/or chemical etching (artificial partial etching). Further, an surface unevenness is not to be construed as being limited to simply have high surface roughness. As an example, surface unevenness should also be construed to include the case in which an uneven structure is artificially formed on the surface of the metal oxide layer using an etching mask at the time of chemical etching.

When an electron transport layer having a predetermined thickness is assumed, a preferable structure capable of increasing a contact interfacial area with the light absorber and smoothly transporting electrons is formed in the case in which the electron transport layer is the porous metal oxide layer. Therefore, the porous metal oxide layer (porous electron transport layer), which is a particularly preferable structure, is referred to as a porous supporter, and a preferable structure of the solar cell according to the present invention will be described in detail. In this case, the porous metal oxide layer may contain metal oxide particles, and have an open porous structure by void spaces between these particles.

When the solar cell according to the present invention is a solar cell including the first electrode; a composite layer positioned on the first electrode and including the light absorber impregnated in pore structures between particles of the porous support layer; a light absorption structure body positioned on the composite layer and formed of the light absorber; the hole transport layer positioned on the light absorption structure body; and the second electrode positioned on the hole transport layer, the solar cell may have a more excellent effect.

In addition, the solar cell according to an exemplary embodiment of the present invention may include a first electrode; a composite layer composed of a porous support layer positioned on the first electrode and containing metal oxide particles and a light absorber containing the solid-solution and filled in pores between the particles of the porous support layer; a hole transport layer positioned on the composite layer and containing an organic hole transport material; and a second electrode positioned on the hole transport layer and facing the first electrode.

The present invention includes all contents disclosed in PCT/KR2013/008270 and PCT/KR2013/008268 applied earlier by the present applicant. Since the composite layer, a content of the light absorber filled in the composite layer, or a structure of the light absorption structure body, and a detailed manufacturing method thereof were disclosed in PCT/KR2013/008270 and PCT/KR2013/008268 applied earlier by the present inventor, a description may refer to the prior applications.

In addition, the solar cell according to an exemplary embodiment of the present invention may also include a first electrode; a porous support layer positioned on the first electrode and containing metal oxide particles; a light absorber positioned in pores of the porous support layer and containing the solid-solution; a hole transport layer positioned on the porous support layer on which the light absorber is formed and containing an organic hole transport material; and a second electrode positioned on the hole transport layer and facing the first electrode.

In the solar cell according to an exemplary embodiment of the present invention, when the light absorption structure body has a form of a light absorber thin film or a light absorber pillar extended from the porous support layer of which pores are filled with the light absorber, or a light absorber pillar protruding from the light absorber thin film, a solar cell having more excellent light efficiency and excellent moisture resistance may be manufactured.

In this case, the porous support layer (porous metal oxide layer) containing the metal oxide particles may simultaneously serve as a supporter supporting the light absorber and an electron transport layer transporting photoelectrons of photoelectrons-photoholes generated by light absorption in the light absorber to the first electrode.

In the solar cell according to an exemplary embodiment of the present invention, the first electrode may be a transparent substrate provided with a transparent electrode, wherein any transparent electrode and transparent substrate may be used as long as they are generally used in a solar cell field. The transparent substrate may be a rigid or flexible substrate. The transparent electrode may be a transparent conductive electrode ohmic contacting the metal oxide (particles) forming the porous support layer. As a substantial example, the transparent electrode may be made of at least one selected from fluorine doped tin oxide (FTC), indium doped tin oxide (ITO), ZnO, carbon nanotube (CNT), graphene, and a composite thereof. As the transparent substrate, any transparent substrate may be used as long as it may serve as a supporter for supporting a structure on the substrate and transmitting light. As an example, the substrate may be a rigid substrate including a glass substrate or a flexible substrate containing polyethylene terephthalate (PET), polyethylene naphthalate (PEN), polyimide (PI), polycarbonate (PC), polypropylene (PP), triacetylcellulose (TAC), polyethersulfone (PES), or the like.

The porous support layer serving as an electron carrier transporting electrons and/or the supporter of the light absorber may have a porosity (apparent porosity) corresponding to a general porosity of a supporter or an electron carrier on which a dye (inorganic semiconductor quantum dot) is supported in a general dye-sensitized solar cell or inorganic semiconductor based solar cell using an inorganic semiconductor quantum dot as the dye, but the porosity may be preferably, 30 to 65%, more preferably 40 to 60%. Due to this porosity, an easy and continuous flow of the electron may be secured in the porous metal oxide, a relative content of the light absorber in the composite layer may be increased, and a contact area between the metal oxide and the light absorber may be increased.

The porous support layer serving as an electron carrier transporting electrons and/or the supporter of the light absorber may have a general specific surface area of the supporter or the electron carrier on which the dye (inorganic semiconductor quantum dot) is supported in the general dye-sensitized solar cell or inorganic semiconductor based solar cell using an inorganic semiconductor quantum dot as the dye, but the specific surface area may be preferably 10 to 100 m²/g. This specific surface area is a specific surface area at which light absorbance may be increased even in the case of not excessively increasing a thickness of the solar cell, and the photoelectron-photohole generated by light may be easily separated from each other to move via the metal oxide or light absorber itself before the photoelectron-photohole are recombined to thereby be annihilated.

The porous support layer may have a general thickness of the supporter or the electron carrier on which the dye (inorganic semiconductor quantum dot) is supported in the general dye-sensitized solar cell or inorganic semiconductor based solar cell using an inorganic semiconductor quantum dot as the dye, but may have a thickness of preferably 10 μm or less, more preferably 5 μm or less, further more preferably, 1 μm or less, and most preferably 800 nm or less. In the case in which the thickness is more than 10 μm, a distance at which the photoelectron generated from the light is transported to an external circuit is increased, such that efficiency of the solar cell may be deteriorated. Further, in the case in which the thickness of the porous metal oxide (layer) is 1000 nm or less, preferably 800 nm or less, the composite layer in which the light absorber is impregnated into the porous metal oxide; and the light absorption structure body may be simultaneously and stably formed by a single process of applying and drying a light absorber solution in which the light absorber is dissolved, and at least 15% of the surface of the composite layer may be covered by the light absorption structure body.

The porous support layer serving as the electron carrier or the supporter of the light absorber may be a general metal oxide used in conducting photoelectrons in the solar cell field. For example, the porous support layer may be made of one or at least two materials selected from Ti oxide, Zn oxide, In oxide, Sn oxide, W oxide, Nb oxide, Mo oxide, Mg oxide, Zr oxide, Sr oxide, Yr oxide, La oxide, V oxide, Al oxide, Y oxide, Sc oxide, Sm oxide, Ga oxide, In oxide, and Sr—Ti oxide, or a mixture or composite thereof.

In the solar cell according to an exemplary embodiment of the present invention, the porous support layer may be a layer (porous metal oxide layer) formed of a plurality of metal oxide particles and having open pores.

In addition, a particle size of the metal oxide particles forming the porous support layer may be preferably 5 to 500 nm. In the case in which the particle size is less than 5 nm, an cavity (pore) is excessively small, such that the light absorber may not be sufficiently attached into the cavity, and in the case in which the particle size is more than 500 nm, a specific surface area of the porous support layer per unit area may be decreased, and thus, an amount of the light absorber per unit area may be decreased, such that efficiency of the solar cell may be deteriorated.

Further, the porous support layer may have a coating layer made of one or at least two materials selected from Ti oxide, Zn oxide, In oxide, Sn oxide, W oxide, Nb oxide, Mo oxide, Mg oxide, Zr oxide, Sr oxide, Yr oxide, La oxide, V oxide, Al oxide, Y oxide, Sc oxide, Sm oxide, Ga oxide, In oxide, Sr—Ti oxide, and a composite thereof in order to improve interfacial contact between the metal oxide particles forming the support layer. Generally, in order to improve the interfacial contact, the coating may be performed in a range in which the cavity of the porous metal oxide layer is not filled.

The solar cell according to an exemplary embodiment of the present invention may further include a metal oxide thin film positioned between the first electrode and the porous support layer. That is, a dense electron transport film may be further provided between the first electrode and the porous support layer, wherein the electron transport film may be a metal oxide thin film.

In this case, a material of a metal oxide thin film may be, for example, at least one material selected from Ti oxide, Zn oxide, In oxide, Sn oxide, W oxide, Nb oxide, Mo oxide, Mg oxide, Zr oxide, Sr oxide, Yr oxide, La oxide, V oxide, Al oxide, Y oxide, Sc oxide, Sm oxide, Ga oxide, In oxide, Sr—Ti oxide, and a composite thereof and be the same or different from the metal oxide particles of the porous support layer.

The metal oxide thin film may mainly serve to allow electrons to more smoothly move from the porous support layer to the first electrode.

In order to provide a smooth movement path of electrodes between the first electrode and the porous support layer, a thickness of the metal oxide thin film may be preferably 30 nm or more, substantially 50 nm to 100 nm.

The light absorber containing the above-mentioned solid-solution may be positioned in the pores of the above-mentioned porous support layer, and the open pores of the porous support layer may be partially or entirely filled with the light absorber. In detail, the light absorber may be positioned in the open pores of the porous support layer, be attached to surfaces of the metal oxide particles forming pore surfaces of the open pores, or entirely fill the inside of the open pores. In the case in which the light absorber fills the inside of the open pores, power conversion efficiency may be further increased.

That is, the solar cell according to the present invention may be divided into a structure in which the light absorber does not fill a pore structure of the porous support layer and a structure in which the light absorber fills the inside of the open pores of the porous support layer. In the present invention, in the case of a composite layer in which the light absorber fills empty spaces between the porous particles of the porous support layer, the solar cell may have more excellent effect. Therefore, this layer is separately referred to as the composite layer and will be described in detail.

Hereinafter, first, the case in which the light absorber is positioned in the open pores of the porous support layer and does not entirely fill the pores of the porous support layer will be described.

In this case, the surface of the porous support layer in which the light absorber is positioned may include the surface by the open pores of the porous support layer. A state in which the light absorber is provided in the surface by the open pores includes a state in which the light absorber is provided while contacting the metal oxide particles in the pores of the porous support layer. The light absorber is provided in the surface of the porous support layer, such that the light absorber may contact the metal oxide particles of the porous support layer and contact the organic hole transport material of the hole transport layer covering the porous support layer while filling the pores of the porous support layer. Therefore, the hole transport layer fills in the open pores of the porous support layer while covering an upper portion of the porous support layer, such that the hole transport layer may have a structure in which the hole transport layer and the porous support layer are connected to each other.

More specifically, in the case in which the light absorber is attached to the surface of the metal oxide particle forming the pore surface, the light absorber may have a particle shape in which solid-solution particles are separated from each other while forming islands or form a discontinuous layer having a film shape in which the solid-solution particles are discontinuously connected to each other or a continuous layer having a film shape in which the solid-solution particles are continuously connected to each other.

In the solar cell according to an exemplary embodiment of the present invention, the light absorber may be attached to the surface of the metal oxide particle forming the pore surface.

The light absorbers may have an island shape in which the solid-solution particles are uniformly distributed to be spaced apart from each other on the surface of the metal oxide of the porous support layer, or a film shape.

In the light absorber, the solid-solution particles may form the discontinuous or continuous layer on the surface of the metal oxide of the porous support layer.

In the case in which the light absorber is configured to include the discontinuous layer of the solid-solution particles, in the light absorber having a shape of the discontinuous layer, the solid-solution particle contacts at least one adjacent solid-solution particle while forming a grain boundary and pores separating the particles from each other are homogeneously present between the solid-solution particles, such that entirely, the light absorber may have a film shape configured of the solid-solution particles but may include a porous structure in which pores penetrating through the film are present.

Further, in the light absorber, the solid-solution particles may form a uniform film, which is the continuous layer, on the surface of the metal oxide particle of the porous support layer. In the case in which the light absorber is configured to include the continuous layer of the solid-solution particle, the light absorber having the continuous layer shape may have a structure in which the solid-solution particles contact all of the solid-solution particles adjacent thereto while forming grain boundaries to thereby be continuously connected to each other and entirely have a film shape. In this case, the continuous layer may include a dense film in which pores are not present, a film in which closed pores are present at triple points of grain boundaries, or a film in which pores penetrating through the film in a thickness direction are partially non-uniformly present.

The solid-solution particle may have an average particle size of 2 nm to 500 nm, and the film (continuous or discontinuous layer) of the solid-solution particle may have a thickness of 2 nm to 500 nm.

Hereinafter, the case in which the light absorber fills all of the open pores of the porous support layer to form a composite layer, which is more preferable in the present invention, will be described in detail.

The composite layer may be a layer in which the porous support layer serving as the electron carrier and/or the supporter of the light absorber and the light absorber are mixed. The composite layer has a structure in which the light absorber is positioned in the open pores of the porous support layer and fills some or all of the pores of the porous support layer, and the structure in which the light absorber fills all of the pores is more preferable.

In detail, the composite layer may contain a plurality of metal oxide particles forming the porous support layer serving as the electron carrier and/or the supporter of the light absorber and the light absorbers and may have a structure in which the light absorber fills the pores of the porous support layer containing the metal oxide particles. The solid-solution particles of the light absorber contained in the composite layer may have an average particle size of 2 nm to 500 nm.

Most preferably, the solar cell according to an exemplary embodiment of the present invention further includes the light absorption structure body having a form of a light absorber thin film or a light absorber pillar extended from the porous support layer of which pores are filled with the light absorber, that is, the composite layer, or a light absorber pillar protruding from the light absorber thin film. The reason is that in this case, power conversion efficiency of the solar cell is significantly excellent.

As described above, the solar cell according to an exemplary embodiment of the present invention may include: the composite layer including the porous support layer serving as the electron carrier or the supporter of the light absorber and the light absorber; and the light absorption structure body extended from the composite layer and positioned on the composite layer, wherein the light absorption structure body may have a form of the light absorber thin film extended from the composite layer; the light absorber pillar extended from the composite layer; or the light absorber thin film extended from the composite layer and the light absorber pillar protruding from the light absorber thin film.

That is, the light absorption structure body may have a thin film structure, a thin film structure provided with surface unevenness such as a pillar, or a structure in which a plurality of pillars (a plurality of protrusion structures spaced apart from each other) are arranged.

In the solar cell according to an exemplary embodiment of the present invention, the light absorber containing the above-mentioned solid-solution absorbing light to generate photohole-photoelectron pairs is present in the composite layer and the light absorption structure body. Due to this structure, even in the case of a significantly thin film type solar cell, the solar cell may have a high light absorption rate.

In the solar cell according to an exemplary embodiment of the present invention, the light absorption structure body may have a structure extended from the composite layer. The extension structure as described above may mean a structure in which the light absorber contained in the composite layer and the light absorption structure body are integrated with each other. Since the light absorption structure body was disclosed in detail in PCT/KR2013/008270 and PCT/KR2013/008268 applied by the present inventor before applying for the present invention, the light absorption structure body will not be described in detail. However, briefly describing the light absorption structure body, there are various methods such as a method of forming the light absorption structure body by adjusting an amount of a light absorber solution, a concentration of the light absorber solution, and/or a thickness of the porous electron carrier, a method using a non-solvent, a method using a mixed solvent, an etching method, and the like. Particularly, a means of applying the light absorber solution several times and/or the above-mentioned method are combined, which is preferable in view that the structure may be stably adjusted.

The light absorption structure body may be formed simultaneously with the light absorber contained in the composite layer by the single process or grow from the light absorber contained in the composite layer.

As described above, the light absorption structure body has the extended structure from the composite layer, such that a loss by scattering at the time of movement of the photohole between the composite layer and the light absorption structure body may be prevented, such that the solar cell having high power conversion efficiency may be manufactured. That is, the above-mentioned extension structure may mean a structure in which one end of the pillar of the extended light absorption structure body is coupled to the composite layer, a structure in which one surface of the thin film of the light absorber structure body is coupled to the composite layer, a structure in which the light absorption structure body and the composite layer are integrated with each other, a structure in which the light absorption structure body and the light absorber contained in the composite layer are integrated with each other, a structure in which the light absorption structure body is formed by growth from the composite layer, or a structure in which the light absorption structure body is formed by growth from the light absorber contained in the composite layer.

In the solar cell according to an exemplary embodiment of the present invention, the light absorption structure body may have an uneven structure such as the pillar.

According to the present invention, when the light absorption structure body including the pillar is provided, the photoelectron generated in the light absorber may be significantly smoothly and effectively separated and moved by a wide contact area between the porous support layer of the composite layer and the light absorber, and the photohole generated in the light absorber may be moved by the pillar protruding and extended from the composite layer in a predetermined direction, that is, a direction toward the second electrode, and movement toward a plane parallel with the electrode (second electrode) is minimized, such that the photohole may be effectively moved, and a loss by recombination may be prevented.

Further, in the case in which the hole transport layer is further formed on the light absorption structure body, a contact area between the second electrode or the organic hole transport material of the hole transport layer and the light absorber (light absorber of the light absorption structure body) may be increased by the unevenness due to the pillar, such that the photohole may be effectively separated, and effective movement of the photohole may be secured. In addition, a loss of photocurrent may be prevented, a photo active region may be increased, and the photoelectron and photohole may be effectively separated and moved, such that a miniaturized solar cell may be implemented as compared to the case of designing a solar cell having the same power.

One or at least two factors selected from a length of the pillar (that is, a size of the pillar in a direction from the porous support layer toward the second electrode), a diameter of the pillar (that is, a size of the pillar in a direction vertical to a length direction of the pillar), a shape of the pillar, and a density of the pillar may affect the contact area between the light absorber and the organic hole transport material of the hole transport layer, photohole movement efficiency through the pillar, interfacial resistance between the pillar and the hole transport layer, and the like.

In detail, the length, the diameter, and the density of the pillar may mainly affect a surface uneven structure and a degree of unevenness by the light absorption structure body positioned on the composite layer.

The surface uneven structure and the degree of unevenness by the light absorption structure body may mainly affect the contact area between the light absorber and the second electrode or the light absorber and the organic hole transport material of the hole transport layer, and affect a degree of additional light absorption depending on an increase in the photo active region by the light absorption structure body.

The length and the diameter of the pillar may mainly affect a movement path of the photohole moving through the light absorption structure body. In detail, as a surface of the pillar is covered by the organic hole transport material of the hole transport layer, the photohole moving from the composite layer to the pillar may move to the organic hole transport material of the hole transport layer through a side surface of the pillar and a distal end of the pillar. In addition, the diameter of the pillar may affect movement easiness of the photohole moving from the light absorber of the composite layer to the pillar, that is, a movement length of the photohole moving from the light absorber of the composite layer to the pillar in the composite layer, and affect interfacial resistance between the pillar and the composite layer.

In this case, when the diameter of the pillar is excessively large, the movement path of the photohole in a direction toward the side surface of the pillar is long, such that annihilation may be generated by recombination in the pillar, and when the diameter of the pillar is excessively small, until the photohole in the composite layer is released to the pillar, resistance is increased such that there is a risk that recombination of the photoelectron-photohole will be increased and interfacial resistance between the pillar and the composite layer will be increased.

Further, in the case in which the length of the pillar is excessively long, the movement path of the photohole in the length direction of the pillar is long, such that annihilation may be generated by recombination in the pillar, and in the case in which the length of the pillar is excessively short, an effect of increasing the contact area by an increase of surface unevenness as described above may be insufficient.

The density of the pillar (the number of existing pillar per unit surface area of the composite layer) may affect a flow amount of the photohole capable of moving from the composite layer to the organic hole transport material of the hole transport layer per time, that is, a movement amount of the photohole in the light absorption structure body, together with the diameter and the length of the pillar. In addition, even in the case of the pillar made of the light absorber having the same volume, the movement path of the photohole, a contact area between the pillar and the composite layer, and a contact area between the pillar and the organic hole transport material of the hole transport layer may be affected depending on a shape of the pillar.

The diameter, the length, and/or the density of the pillar may be suitably controlled depending on use, capacity, a size, or the like, of the solar cell to be designed based on the above-mentioned technical reasons.

As an example, the pillar may be a nanopillar. As the pillar is the nanopillar, it is possible to minimize annihilation of the photohole at the time of movement of the photohole in the pillar while maximizing the contact area between the pillar and the organic hole transport material of the hole transport layer, and maximize movement efficiency of the photohole through the distal end (one end in the direction toward the second electrode) of the pillar and the side surface of the pillar.

As an example, the pillar may have one or at least two column shapes selected from a polygonal column shape, a circular column shape, and an oval column shape, or an acicular or wire shape. Particularly, the pillar having the column shape may be more preferable. The reason is that when the pillar has the column shape, it is possible to minimize annihilation by recombination at the time of movement of the photohole in the pillar while maximizing the contact area between the pillar and the organic hole transport material of the hole transport layer, and maximize the contact area between the pillar and the composite layer. In this case, the column shape may be referred to as a plate shape when the length of the pillar is shorter than the diameter of the pillar.

As an example, the diameter of the pillar may be 100 nm to 100,000 nm, and a thickness of the pillar may be 10 nm to 1,000 nm. As described above, the light absorber of the composite layer and the light absorption structure body may be simultaneously formed by the single process or the light absorption structure body may grow from the light absorber of the composite layer to thereby have the extended structure therefrom, such that one end of the pillar may be positioned in the composite layer. In this case, a diameter of the pillar in the composite layer may be 10 nm to 5,000 nm, the length thereof may be 50 nm to 5000 nm, and a diameter of the pillar protruding from the composite layer may be 100 nm to 100,000 nm, and the thickness of the pillar may be 10 nm to 1,000 nm. The diameter and/or length of the pillar is a diameter and/or length at which the photohole may move from the composite layer to the pillar via a shorter path, the contact area between the composite layer and pillar may be increased, a photo active region may be increased by the pillar, and photohole annihilation in the pillar may be effectively prevented.

As an example, the pillar protruding from the composite layer to thereby be present on the composite layer may have a density at which the pillar covers 5% or more, preferably 30% or more of a surface area based on the entire surface area of an upper surface of the composite layer on which the light absorption structure body is positioned. In the case in which the density of the pillar is less than 5% of the surface area of the upper surface of the composite layer, an effect caused by the pillar structure may be insignificant.

In the case in which the density of the pillar is excessively high, the light absorption structure body has a structure corresponding to that of the light absorber thin film formed of a porous or dense film rather than a form of islands spaced apart from each other, such that the upper limit of the density of the pillar may reach 100%. However, in view of island shaped structures of the pillars spaced apart from each other, the density of the pillar may be 80% or less based on the entire surface area of the upper surface of the composite layer.

In the solar cell according to an exemplary embodiment of the present invention, the light absorption structure body may include an aggregation structure body in which a plurality of pillars are aggregated to form a polygonal column shape, a circular column shape, or an oval column shape.

That is, in the light absorption structure body, a plurality of pillars may be aggregated with each other while being spaced apart from each other, and the aggregated shape may form the polygonal column shape, the circular column shape, or the oval column shape, and the light absorption structure body may have a shape in which a plurality of aggregation structure bodies are arranged to be spaced apart from each other.

The aggregation structure body may have a structure in which each of the pillars forming the aggregation structure body is independently extended from the composite layer or extended via a single root from the composite layer and then, divided into the plurality of pillars.

That is, the plurality of pillars forming the aggregation structure body may be individually extended from the composite layer, respectively. Alternatively, the plurality of pillars are bonded to each other at a stump thereof (a region adjacent to the composite layer), such that the aggregation structure body itself may be extended from the composite layer.

In detail, the aggregation structure body extended via the single root from the composite layer and then, divided into the plurality of pillars may be formed by partially etching the light absorber having the polygonal column shape, the circular column shape, or the oval column shape extended from the composite layer using a dry-etching method including a plasma etching method.

That is, the aggregation structure body may be formed by dry etching the light absorber grown from the composite layer to protrude in polygonal column shape, the circular column shape, or the oval column shape so that a plurality of pillars are formed at an end portion (one end toward the second electrode) while maintaining a single column shape at the stump portion thereof.

In the structure in which the plurality of pillars are extended from the composite layer while having the single stump, the contact area between the composite layer and the pillar may be increased, and pillars having an ultra-fine structure are formed, thereby making it possible to increase the contact area between the pillar and the hole transport material and the density of the pillar and more effectively prevent annihilation of the photohole.

In the solar cell according to the exemplary embodiment of the present invention, the light absorption structure body may be the light absorber thin film extended from the composite layer or the light absorber thin film provided with the above-mentioned light absorber pillar. In this case, a thickness of the light absorber thin film may be 10 nm to 1,000 nm.

In the solar cell according to an exemplary embodiment of the present invention, the light absorption structure body having a form of the thin film, the pillar, or the thin film provided with the pillar may be partially etched by the dry-etching. The dry-etching of the light absorption structure body includes the plasma etching, and as the light absorption structure body is partially etched by the dry-etching, in the case of the pillar, the pillar may be further fined, and additional uneven portions except for original uneven portions of the pillar itself may be further formed, and in the case of the thin film, uneven portions may be formed on a surface of the thin film. Therefore, the contact area with the hole transport layer may be more effectively increased, and at the time of movement (movement in the direction toward the second electrode) of the photohole generated in the light absorber, the movement path may be more effectively limited.

As described above, as the light absorption structure body has the structure extended from the composite layer, in the case in which the light absorption structure body includes the pillar, the pillar may have a structure in which one end thereof is buried in the composite layer. That is, as the light absorption structure body is formed simultaneously with the light absorber contained in the composite layer by a single process or grows from the light absorber contained in the composite layer, one end of the pillar adjacent to the light absorber may be positioned in the surface of the light absorber or into the light absorber, and the other end of the pillar may protrude upwardly from the surface of the light absorber to form a protrusion structure such as an island. The structure in which one end of the pillar is buried in the light absorber may improve separation and movement efficiency of photo-charges generated in the light absorption structure body.

In the solar cell according to an exemplary embodiment of the present invention, the hole transport layer may be a solid-phase organic hole transport layer containing the organic hole transport material.

In the solar cell according to an exemplary embodiment of the present invention, in the case in which the light absorber is provided in the porous support layer in a form of independent particles, the discontinuous layer, or the continuous layer, the hole transport layer may be formed so as to fill the cavity of the porous support layer and cover the upper portion of the porous support layer. That is, a structure in which the light absorber is provided in the pores of the porous support layer having an open pore structure while contacting the metal oxide particles, and the organic hole transport material of the hole transport layer fills the cavity of the porous support layer may maximize a photo sensitive region corresponding to a region at which light may be absorbed, similarly to a percolation structure of an organic solar cell, and separation efficiency of an exciton may be increased.

In the solar cell according to an exemplary embodiment of the present invention, in the case in which the light absorber fills the open pore structure of the porous support layer to form the composite layer or the case in which the light absorption structure body is formed on the composite layer, the solar cell may include a solid-phase hole transport layer positioned between the second electrode and the composite layer or the second electrode and the composite layer on which the light absorption structure body is formed.

In the case of the composite layer on which the light absorption structure body is formed, the hole transport layer may be a film covering the surface of the light absorption structure body or be a film covering both of the surface of the light absorber pillar and the surface of the composite layer on which the pillar does not exist.

A surface of the hole transport layer adjacent to the second electrode may have an uneven surface by the pillar or a flat surface.

In the solar cell according to an exemplary embodiment of the present invention, the organic hole transport material of the hole transport layer may be one or at least two selected from thiophene based materials, paraphenylenevinylene based materials, carbazole based materials, and triphenylamine based materials. When the light absorber contains the solid-solution of the organic-metal halide, the organic hole transport material may be preferably one or two or more selected from the thiophene based materials and the triphenylamine based materials. More preferably, the organic hole transport materials is a triphenylamine based organic hole transport material. Therefore, the solar cell may have photoelectric conversion efficiency further improved by energy matching with the solid-solution of the organic-metal halide.

In detail, the organic hole transport material may satisfy the following Chemical Formula 4.

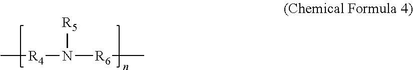

R₄ and R₆ are each independently (C6-C20)arylene, R₅ is (C6-C20)aryl, arylene of R₄ or R₆ or aryl of R₅ may be substituted with at least one selected from a group consisting of halogen, (C1-C30)alkyl substituted or unsubstituted with halogen, (C6-C30)aryl, (C2-C30)heteroaryl substituted or unsubstituted with (C6-C30)aryl, 5- to 7-membered heterocycloalkyl, 5- to 7-membered heterocycloalkyl fused with one or more aromatic rings, (C3-C30)cycloalkyl, (C6-C30)cycloalkyl fused with one or more aromatic rings, (C2-C30)alkenyl, (C2-C30)alkinyl, cyano, carbazolyl, (C6-C30)ar(C1-C30)alkyl, (C1-C30)alkyl(C6-C30)aryl, nitro, and hydroxyl, and n is a natural number of 2 to 100,000.

In Chemical Formula 4, R₄ and R₆ may be each independently phenylene, naphthylene, biphenylene, terphenylene, anthrylene indenylene, fluorenylene, phenanthrylene, triphenylenylene, pyrenylene, perylenylene, chrysenylene, naphthacenylene, or fluoranthenylene, and R₅ may be phenyl, naphthyl, biphenyl, terphenyl, anthryl, indenyl, fluorenyl, phenanthryl, triphenylenyl, pyrenyl, perylenyl, chrysenyl, naphthacenyl, or fluoranthenyl.

In detail, the organic hole transport material may be one or two or more selected from poly[3-hexylthiophene] (P3HT), poly[2-methoxy-5-(3′,7′-dimethyloctyloxyl)]-1,4-phenylene vinylene (MDMO-PPV), poly[2-methoxy-5-(2″-ethylhexyloxy)-p-phenylene vinylene] (MEH-PPV), poly(3-octyl thiophene) (P3OT), poly(octyl thiophene) (POT), poly(3-decyl thiophene) (P3DT), poly(3-dodecyl thiophene (P3DDT), poly(p-phenylene vinylene) (PPV), poly(9,9′-dioctylfluorene-co-N-(4-butylphenyl)diphenyl amine (TFB), polyaniline, [2,2′,7,7′-tetrakis (N,N-di-p-methoxyphenyl amino)-9,9′-spirobifluorene] (Spiro-MeOTAD), CuSCN, CuI, poly[2,1,3-benzothiadiazole-4,7-diyl[4,4-bis(2-ethylhexyl-4H-cyclopenta [2,1-b:3,4-b′]dithiophene-2,6-diyl]] (PCPDTBT), poly[(4,4′-bis(2-ethylhexyl)dithieno[3,2-b:2′,3′-d]silole)-2,6-diyl-alt-(2,1,3-benzothiadiazole)-4,7-diyl] (Si-PCPDTBT), poly((4,8-diethylhexyloxyl) benzo([1,2-b:4,5-b′]dithiophene)-2,6-diyl)-alt-((5-octylthieno[3,4-c]pyrrole-4,6-dione)-1,3-diyl) (PBDTTPD), poly[2,7-(9-(2-ethylhexyl)-9-hexyl-fluorene)-alt-5,5-(4′, 7,-di-2-thienyl-2′,1′, 3′-benzothiadiazole)] (PFDTBT), poly[2,7-9,9-(dioctyl-fluorene)-alt-5,5-(4′,7′-di-2-thienyl-2′,1′,3′-benzothiadiazole)] (PFO-DBT), poly[(2,7-dioctylsilafluorene)-2,7-diyl-alt-(4,7-bis(2-thienyl)-2,1,3-benzothiadiazole)-5,5′-diyl] (PSiFDTBT), poly[(4,4′-bis(2-ethylhexyl)dithieno[3,2-b:2′,3′-d]silole)-2,6-diyl-alt-(2,1,3-benzothiadiazole)-4,7-diyl] (PSBTBT), poly [[9-(1-octylnonyl)-9H-carbazole-2,7-diyl]-2,5-thiophenediyl-2,1,3-benzothiadiazole-4,7-diyl-2,5-thiophenediyl] (PCDTBT), poly(9,9′-dioctylfluorene-co-bis(N,N′-(4,butylphenyl))bis(N,N′-phenyl-1,4-phenylene)diamine (PFB), poly(9,9′-dioctylfluorene-co-benzothiadiazole (F8BT), poly(3,4-ethylenedioxythiophene) (PEDOT), poly(3,4-ethylenedioxythiophene) poly(styrenesulfonate) (PEDOT:PSS), poly(triarylamine) (PTAA), poly(4-butylphenyl-diphenyl-amine), and a copolymer thereof. The compound names may be represented by only abbreviations generally used in the art.

In the solar cell according to an exemplary embodiment of the present invention, the hole transport layer may further contain one or at least two additives selected from tertiary butyl pyridine (TBP), lithium bis(trifluoro methanesulfonyl)imide (LiTFSI), and tris(2-(1H-pyrazol-1-yl)pyridine)cobalt(III). The hole transport layer contains the additive, such that a fill factor, a short-circuit current, or an open circuit voltage may be increased. The additive may be added at a content of 0.05 to 100 mg per 1 g of the organic hole transport material of the hole transport layer.

In the solar cell according to an exemplary embodiment of the solar cell, as the second electrode, which is a counter electrode of the porous support layer, any electrode may be used as long as it is generally used in the solar cell field. As a substantial example, the second electrode may be made of at least one material selected from gold, silver, platinum, palladium, copper, aluminum, carbon, cobalt sulfide, copper sulfide, nickel oxide, and composites thereof.

In the case in which the light absorption structure body is formed, a surface of the second electrode may have surface unevenness by the light absorption structure body. However, the surface of the second electrode may also be a flat surface.

The above-mentioned solar cell may be in a state in which the solar cell is encapsulated by a transparent resin layer enclosing a surface of the solar cell, wherein this transparent resin layer may serve to prevent transmission of moisture and/or oxygen while protecting the surface of the solar cell. As a transparent resin of the transparent resin layer, any resin may be used as long as it may be used as an encapsulant for protecting an organic solar cell. As a specific example, the transparent resin may include a polyethylene based resin, a polypropylene based resin, a cyclic polyolefin based resin, a polystyrene based resin, an acrylonitrile-styrene copolymer, an acrylonitrile-butadiene-styrene copolymer, a polyvinyl chloride based resin, a fluorine based resin, a poly(meth)acrylic resin, a polycarbonate based resin, and a mixture thereof. Further, the transparent resin layer may further contain an adsorbent adsorbing oxygen and/or moisture for preventing transmission of oxygen and/or moisture, and this adsorbent may be distributed on the transparent resin layer in a particle phase or buried in the transparent resin layer while forming a predetermined layer. As the above-mentioned adsorbent, all of the materials that are known to adsorb moisture and/or oxygen may be used. A specific example thereof may include an alkali earth metal such as Ca or Sr, an alkali earth metal oxide such as CaO or SrO, Fe, ascorbic acid, a hydrazine compound, or a mixture thereof.

Hereinafter, a manufacturing method of a solar cell according to the exemplary embodiment of the present invention will be described in detail. In this case, a description of the material or the configuration described in detail in the above-mentioned solar cell will be omitted.

The manufacturing method according to an exemplary embodiment of the present invention may include; a) manufacturing a porous support layer on a first electrode; b) applying and drying a light absorber solution in which a light absorber containing the above-mentioned solid-solution on the porous support layer is dissolved; and c) applying and drying a hole transport solution in which an organic hole transport material is dissolved to form a hole transport layer.

In this case, the first electrode may be formed on a transparent substrate, which is a rigid substrate or flexible substrate, using physical vapor deposition, chemical vapor deposition, or thermal evaporation.

The porous support layer in step a) may be manufactured by applying and drying and heat-treating slurry containing metal oxide particles on the first electrode.

In detail, in step a), the slurry containing the metal oxide particles is applied on the first electrode and the applied slurry layer is dried and heat-treated, thereby manufacturing the porous support layer. Application of the slurry may be performed by one or more methods selected from a screen printing method; a spin coating method; a bar coating method; a gravure coating method; a blade coating method; and a roll coating method.

Factors mainly affecting a specific surface area of a porous metal oxide layer, which is the porous support layer, and an open pore structure are an average particle size of the metal oxide particles and a heat-treating temperature. The average particle size of the metal oxide particles may be 5 to 500 nm, and heat-treatment may be performed at 200 to 600° C. under air atmosphere.

The specific surface area of the porous support layer in step a) may be 10 to 100 m²/g, and a thickness of the porous support layer manufactured by heat-treating the slurry after drying the applied slurry may be preferably 50 nm to 10 μm, more preferably 50 nm to 5 μm, and most preferably 50 nm to 1 μm. In order to simultaneously manufacture the above-mentioned composite layer and light absorption structure body using application of an absorber solution, it is preferable to adjust the thickness of the porous support layer at 1 μm or less. Therefore, an application thickness of the slurry may be adjusted so that the thickness of the porous support layer becomes preferably 50 nm to 800 nm, more preferably 50 nm to 600 nm, further more preferably 100 nm to 600 nm, and most preferably 200 nm to 600 nm.

In the manufacturing method of a solar cell according to an exemplary embodiment of the present invention, after step a) and before step b), a post-processing step of impregnating the porous support layer into a metal precursor-dissolved solution containing a metal element of the metal oxide particles may be further performed.

The metal precursor in the post-processing step may be a metal halide including a metal chloride, a metal fluoride, and a metal iodide, and a metal of the metal precursor may be one or at least two selected from Ti, Zn, In, Sn, W, Nb, Mo, Mg, Zr, Sr, Yr, La, V, Al, Y, Sc, Sm, Ga, and In, and be the same as or different from the metal of the metal oxide particles.

The metal precursor-dissolved solution may be a solution in which the metal precursor is dissolved at a low concentration of 10 to 200 mM, and the post-processing step may be performed by separating and recovering the porous support layer after the impregnation is performed for 6 to 18 hours.

In the post-processing, when the porous support layer manufactured by applying the slurry containing the metal oxide particles on the first electrode and then heat-treating the applied slurry is left in a significantly weak metal precursor-dissolved solution, a significantly small metal oxide particle is generated by hydrolysis even at room temperature with the passage of time to thereby be attached to the metal oxide particle of the porous support layer.

Significantly fine metal oxide particles (post-processing particles) generated by this post-processing are present between particles of the porous support layer having relatively many defects, such that the efficiency of a device may be increased by improving a flow of the electrons and preventing annihilation, and an amount of the attached light absorber may also be increased by increasing the specific surface area of the porous support layer.

In this case, before performing the forming of the porous support layer, forming a thin film of the metal oxide on the first electrode (a thin film forming step) may be further performed. The thin film forming step may be performed by a chemical or physical deposition method used in a general semiconductor process and performed by a spray pyrolysis method (SPM).

A material of a metal oxide thin film may be at least one material selected from Ti oxide, Zn oxide, In oxide, Sn oxide, W oxide, Nb oxide, Mo oxide, Mg oxide, Zr oxide, Sr oxide, Yr oxide, La oxide, V oxide, Al oxide, Y oxide, Sc oxide, Sm oxide, Ga oxide, In oxide, Sr—Ti oxide, and a composite thereof and be the same or different from the metal oxide particles of the porous support layer.

After the porous support layer is manufactured on the first electrode in step a), the forming of the light absorber may be performed in step b).

The forming of the light absorber (step b) may be performed by a significantly simple and rapid process of applying and drying the light absorber solution in which the light absorber containing the above-mentioned solid-solution is dissolved onto the porous support layer.

The above-mentioned solid-solution satisfying Chemical Formula 3 may be prepared by mixing and dissolving one organic-metal halide satisfying Chemical Formula 1 and another organic-metal halide satisfying Chemical Formula 2 so as to have an m ratio according to Chemical Formula 3 and then simply drying the resultant.

Therefore, the light absorber solution may be a solution obtained by drying the solution in which at least two organic-metal halides forming the solid-solution are mixed and dissolved to prepare the solid-solution satisfying Chemical Formula 3, 3-1, or 3-2 and then dissolving the prepared solid-solution in a solvent again.

In addition, as the solid-solution satisfying Chemical Formula 3, 3-1, or 3-2 is formed by simply drying the solution in which at least two organic-metal halides are mixed and dissolved, the light absorber solution may be a solution itself in which at least two organic-metal halides are mixed and dissolved so as to have a desired m ratio according to Chemical Formula 3.

An adjusting method of the structure of the light absorber or the light absorption structure body of the present invention is described in detail in PCT/KR2013/008270 and PCT/KR2013/008268 applied earlier by the present inventor, but in the present invention, an example of a method capable of adjusting the structure by adjusting an application condition of the light absorber solution will be described as follows.

The forming of the light absorber (step b)) may be performed by a significantly simple and rapid process of applying and drying the light absorber solution in which the light absorber containing the above-mentioned solid-solution is dissolved onto the porous support layer.

In more detail, in order to simultaneously manufacture the composite layer and the light absorption structure body positioned on the composite layer by applying the light absorber solution, mainly, a concentration of the light absorber solution, the thickness of the porous support layer (specifically, the porous metal oxide), a porosity of the porous support layer (specifically, the porous metal oxide), and whether or not the light absorber solution remaining on the porous electron carrier forms a film after application is completed may be adjusted.

There is a limitation in that the concentration of the light absorber solution may not be increased more than a concentration of the saturated solution, and even though the film of the light absorber solution remains on the porous support layer, the light absorber solution may continuously permeate toward the porous support layer to thereby be consumed while the composite layer is formed. Therefore, in order to simultaneously manufacture the composite layer and the light absorption structure body positioned on the composite layer by applying the light absorber solution once, the thickness of the porous support layer (specifically, the porous metal oxide) may be mainly controlled.

In the case in which the thickness of the porous support layer is excessively thick, after applying the light absorber solution, the light absorber solution remaining on the composite layer may also be consumed in the composite layer, such that the light absorption structure body may not be manufactured. Even though the light absorption structure body is manufactured, a surface coverage of the composite layer by the light absorption structure body is decreased, such that efficiency improvement may be insufficient. In order to simultaneously manufacture the light absorption structure body while forming the light absorber in the composite layer by the solution application method in the single process, the thickness of the porous support layer (porous metal oxide layer) may be 1000 nm or less, preferably 800 nm or less, and more preferably 600 nm or less. Here, in view of increasing the contact area (interfacial area) between the metal oxide (electron carrier) and the light absorber in the composite layer, the lower limit of the thickness of the porous support layer may be 50 nm.

In the case in which the porosity of the porous support layer is excessively high, after applying the light absorber solution, the light absorber solution remaining on the composite layer may also be consumed in the composite layer, such that the light absorption structure body may not be manufactured. In order to simultaneously manufacture the light absorption structure body while forming the light absorber in the composite layer by applying the light absorber solution, the porosity of the porous support layer may be 30 to 65%, preferably, 40 to 60%.

In order to coat the surface (including the surface by the pores) of the porous support layer with the light absorber or fill the light absorber in the pores of the porous support layer and simultaneously form the light absorption structure body on the electron support layer impregnated with the light absorber using the solution application method, particularly, by applying and drying a single light absorber solution once instead of distributing the light absorber in the porous support layer as particles or a cluster (aggregates of the particles) independent of each other, it is preferable to use a light absorber solution in which the light absorber is dissolved at a high concentration.

A concentration of the high concentration light absorber solution is not particularly limited, but in view of stably and reproducibly manufacturing the composite layer and the light absorption structure body, the concentration of the light absorber of the light absorber solution may satisfy the following Correlation Equation 2, preferably, the following Correlation Equation 2-1.

0.4 M≤Ms≤Msat (Correlation Equation 2)

0.8 M≤Ms≤Msat (Correlation Equation 2-1)

In Correlation Equations 2 and 2-1, Ms is a molar concentration (based on the solid-solution) of the light absorber in the light absorber solution, and Msat is a molar concentration of the light absorber in the light absorber solution in a saturated solution state at room temperature (25° C.). As a non-restrictive example, in considering a non-aqueous polar organic solvent having a vapor pressure of 0.01 mmHg to 10 mmHg at 20° C., Msat may be in a range of 1.1M to 1.8M.

In this case, the molar concentration of the light absorber in the light absorber solution may be increased more than Msat at 20° C. by adjusting a temperature of the light absorber solution to room temperature or more, and application of the light absorber solution may be performed by adjusting a temperature of the porous electrode so as to be equal or similar to a temperature of the light absorber solution heated to thereby maintain a predetermined temperature, or an ambient temperature of a sample at the time of application. This adjustment of the temperature of the light absorber solution, the temperature of the porous electrode at the time of applying the light absorber solution, and/or the ambient temperature at the time of application may be included in a modification example according to the spirit of the present invention. In addition, specific examples of the solvent of the light absorber solution are demonstrated based on 20° C., but at the time of applying the light absorber solution, the vapor pressure of the solvent may be adjusted by adjusting the temperature of the porous electrode and/or the ambient temperature, which may also be included in a modification example according to the spirit of the present invention.

At the time of applying the light absorber solution, a detailed method of applying the light absorber solution so that a liquid-phase film of the light absorber solution remains on the surface of the porous support layer may be changed depending on the application method, but those working in applying a liquid to a substrate to form a material film may control the liquid-phase film to remain by changing process conditions in various application methods.

At the time of applying the light absorber solution, since the porous support layer has the porous structure, in view of uniform application of the solution, treatment of a large area, and a short processing time, the spin coating method may be preferable. At the time of applying the light absorber solution using the spin coating method, an rpm of spin coating at which the light absorber solution may be uniformly applied and the liquid-phase film of the light absorber solution may remain on the porous support layer may be suitable. When rotational force is excessively small at the time of spin coating, it may be difficult to uniformly apply the light absorber solution onto a large-area porous support layer, and when the rotational force is excessively large, the liquid-phase (film) of the light absorber solution may not remain on the porous support layer impregnated with the light absorber solution. Those skilled in the art may deduce various spin coating conditions for allowing the liquid phase film of the light absorber solution to remain on the surface of the support layer while uniformly applying the light absorber solution through repetitive experiments. As a non-restrictive and specific example, the maximum rpm at the time of spin coating is preferably less than 5000 rpm. More stably, the spin coating may be performed preferably at 4000 rpm or less, more preferably, at 3000 rpm or less. In this case, the spin coating may be performed by a multi-step process so as to gradually increase the rpm while satisfying the maximum rpm of 5000 rpm, preferably, 4000 rpm or less, and more preferably 3000 rpm or less. As long as the maximum rpm is 5000 rpm, preferably, 4000 rpm or less, and more preferably 3000 rpm or less, various specific methods that are known as an effective method for uniformly and homogeneously applying a liquid at the time of applying a general liquid using the spin coating method may be used. In this case, in view of uniformly applying the light absorber solution onto the large-area porous support layer in a short time, the minimum rpm at the time of spin coating, may be 100 rpm, preferably 500 rpm, and more preferably 1000 rpm.

An amount of light absorber solution applied at the time of spin coating may be suitably adjusted in consideration of a total pore volume (Vs) of the porous support layer. It is preferable that an amount more than the total pore volume is applied so that the light absorber solution may be uniformly applied even on a large area to uniformly and homogeneously form the composite layer and the light absorption structure body. As a non-restrictive example, the light absorber solution may be applied 10 to 1000 times the total pore volume (Vs). However, in the case of applying the light absorber solution using the spin coating method, since more than a predetermined amount of the light absorber solution may be removed by rotational force, it is preferable that the solution is applied at an amount more than the total pore volume so that the light absorber solution may be easily, uniformly, and homogeneously injected into the pores of the large-area porous electrode. In this case, the light absorber solution applied onto the porous support layer may be continuously or discontinuously put (injected) into the porous support layer during the spin coating or be put (injected) thereinto once at an initiation point in time of the spin coating.

At the time of manufacturing the composite layer and the light absorption structure body by the solution application method of applying the light absorber solution to form the light absorber (including the light absorber of the composite layer and the light absorber of the light absorption structure body), a size (including a thickness in the case of a thin film) of the light absorption structure body formed on the composite layer may be adjusted by adjusting the amount of light absorber solution forming the film and remaining on the porous support layer, the concentration of the light absorber solution, and/or the thickness of the porous support layer.

Here, in the case in which the size of the light absorption structure body is adjusted by the thickness of the porous support layer, when the contact area between the porous support layer and the light absorber is excessively small, power conversion efficiency may be decreased, and the amount of the remaining light absorber solution may have a process variation according to the application method and condition. Therefore, in view of stable, reproducible, and precise adjustment, it is preferable to adjust the size of the light absorption structure body by adjusting the concentration of the light absorber solution. As a non-restrictive example, a light absorption structure body (including a light absorber thin film) having a thickness of 10 nm to 1000 nm may be manufactured by increasing the concentration of the light absorber solution under the condition at which the concentration of the light absorber solution satisfies the Correlation Equation 2, preferably Correlation Equation 2-1 in a state in which the thickness of the porous support layer and application conditions are fixed.

As a solvent of the light absorber solution, any solvent may be used as long as it may dissolve both of the organic halide and the metal halide and be easily volatilized and removed at the time of drying. In detail, the solvent of the light absorber solution includes all of the solvents disclosed in PCT/KR2013/008270 and PCT/KR2013/008268 by the present inventor. As a specific example, the solvent of the light absorber solution may be a non-aqueous polar organic solvent, more specifically, a non-aqueous polar organic solvent having vapor pressure of 0.01 mmHg to 10 mmHg at 20° C. As a non-restrictive example, the solvent of the light absorber solution may be one or at least two selected from gamma-butyrolactone, formamide, N,N-dimethylformamide, diformamide, acetonitrile, tetrahydrofuran, dimethylsulfoxide, diethyleneglycol, 1-methyl-2-pyrrolidone, N,N-dimethylacetamide, acetone, α-terpineol, β-terpineol, dihydroterpineol, 2-methoxyethanol, acetylacetone, methanol, ethanol, propanol, butanol, pentanol, hexanol, ketone, methylisobutyl ketone, and the like. As another specific example, the solvent of the light absorber solution may be a mixed solvent (first mixed solvent) in which at least two non-aqueous polar organic solvents having different vapor pressures from each other are mixed. Here, in the mixed solvent, a vapor pressure of the first solvent having a relatively high vapor pressure may be 2 to 20 times a vapor pressure of the second solvent having a relatively low vapor pressure, and the vapor pressure of the second solvent may be 0.01 to 4 mmHg, preferably 0.1 to 4 mmHg at 20° C.

When a process of applying and drying the light absorber solution is considered as a unit process, the composite layer and the light absorption structure body may be formed by repeating the unit process. Alternatively, the light absorption structure body may be formed on the porous electrode provided with the light absorber by a single unit process. In this case, the composite layer and the light absorption structure body may be formed through a single applying and drying process by increasing the concentration of the light absorber solution.

The concentration of the high concentration light absorber solution is not particularly limited, but in view of stably and reproducibly manufacturing the composite layer and the light absorption structure body, the concentration of the light absorber of the light absorber solution may satisfy the above-mentioned Correlation Equation 2, preferably, Correlation Equation 2-1.

As described above, in view of uniformly applying the solution in the porous structure having a large area in a short time, application may be performed by spin coating. In the case of applying the light absorber solution using the spin coating method, it is preferable that the maximum rpm of a rotational speed at the time of spin coating is not over 5000 rpm so that the film of the light absorber solution may remain on the porous metal oxide layer. In addition, it is preferable that the spin coating is more stably performed at 4000 rpm or less, and more stably, 3000 rpm or less. In this case, when the light absorber solution is applied two times or more at the different rotational speeds under the condition at which the maximum rpm is not over 5000 rpm, the light absorption structure body may be more excellently adjusted. The drying (or annealing) of the applied light absorber solution is not particularly limited, but may be performed, for example, at a temperature of 60 to 150° C. and a normal pressure for 3 to 100 minutes.

At the time of applying the light absorber solution, a method using a non-solvent disclosed in PCT/KR2013/008270 and PCT/KR2013/008268 by the present inventor may also be used. In detail, a method for contacting the applied light absorber solution with the non-solvent in a state in which the light absorber solution is applied on the porous metal oxide layer and the solvent of the applied light absorber solution is not entirely volatilized and removed but remains may be used. Specifically, after application of the light absorber solution using the spin coating method is completed, the non-solvent may be sequentially applied, or after the light absorber solution is injected into a region of the porous electron carrier corresponding to the rotational center, while the porous electron carrier is rotated so as to uniformly disperse the injected light absorber solution, the non-solvent may be re-injected into the region of the porous electron carrier corresponding to the rotational center. The non-solvent of the light absorber may mean an organic solvent in which the light absorber is not dissolved, specifically, an organic solvent in which solubility of the light absorber at 20° C. and 1 atm is less than 0.1M, specifically, less than 0.01M, and more specifically, less than 0.001M. More specifically, the non-solvent of the light absorber may be a non-polar organic solvent, preferably, a non-polar solvent having permittivity (s; relative permittivity) of 20 or less, substantially permittivity of 1 to 20. A specific example of the non-solvent of the light absorber may be one or at least two selected from pentane, hexene, cyclohexene, 1,4-dioxane, benzene, toluene, triethylamine, chlorobenzene, ethylamine, ethylether, chloroform, ethylacetate, acetic acid, 1,2-dichlorobenzene, tert-butylalcohol, 2-butanol, isopropanol, and methylethylketone, but is not limited thereto. In the case of using the non-solvent, the drying (or annealing) may be performed after application of the light absorber solution and application of the non-solvent are performed, and this drying (annealing) may be performed at a temperature of 60 to 150° C. and a normal pressure for 3 to 100 minutes.

After the forming of the light absorber is performed, an etching step of drying etching the light absorber pillar protruding and extended from the composite layer or the light absorber thin film extended from the composite layer may be further performed.

In detail, the dry-etching includes the plasma etching, the light absorber pillar is partially etched by directionality of the etching, which is a property of the dry-etching, such that fineness of the pillar may be implemented. The dry-etching for more finely etching the pillar is to manufacture the light absorber as fine pillar aggregates in the case in which the light absorber having a coarse size protrudes from the composite layer or to increase surface roughness of the light absorber pillar.

In detail, as the plasma at the time of plasma etching, any plasma formed in vacuum or normal pressure may be used. In this case, the pillar aggregates may be formed or surface roughness of the pillar or the film may be entirely increased by adjusting etching power, an etching time, and a kind and amount of gas forming plasma at the time of plasma etching. Since the light absorber previously extended and protruding from the composite layer is allowed to be finely formed, even in the case of performing simple plasma etching without using an etching mask, surface roughness may be additionally increased due to directionality and non-uniformity of the etching.

In detail, at the time of atmospheric plasma etching, at least two etching gases selected from argon, nitrogen, oxygen, and hydrogen may be used, plasma power may be 50 W to 600 W, a plasma etching time may be 10 seconds or 1 hour. In this case, a plasma exposure time may be changed according to the plasma power. In addition, the etching process may be performed by exposure to the plasma for a long time or repetitive exposure to the plasma for a short time (several seconds). A degree of fineness of the pillar and surface roughness of the pillar may be controlled by adjusting the plasma power and/or the etching time at the time of plasma etching.

In the forming of the light absorber, in order to form the light absorber in the porous supporter instead of simultaneously manufacturing the composite layer of which the pores are filled with the light absorber and the light absorption structure body, only the composite layer may be formed without the light absorption structure body or the light absorber may be formed in the porous supporter in a form of an island or a form of a surface coating layer of the metal oxide particles by increasing the thickness or porosity of the porous supporter, applying the light absorber solution at a low concentration, and/or controlling the application method and conditions to adjust the light absorber solution so as not to remain on the surface of the porous supporter at the time of applying the light absorber solution.

As the light absorber is formed only in the porous supporter, the thickness and the porosity of the porous supporter may affect an attachment amount of the light absorber. In the case in which the attachment amount of the light absorber is excessively small, since power conversion efficiency of the solar cell may be decreased, it is preferable to design the thickness and porosity of the porous supporter (ex. porous metal oxide layer) in consideration of the attachment amount of the light absorber.

Therefore, preferably, the light absorber may be adjusted so as to be formed only in the porous supporter by adjusting the concentration of the light absorber solution and/or adjusting the light absorber solution so as not to remain on the surface of the porous supporter at the time of applying the light absorber solution.

In the case in which the light absorber is formed only in the porous supporter by adjusting the light absorber solution so as not to remain, the light absorber solution having any concentration may be used. More specifically, the light absorber solution having a concentration within the above-mentioned range and a concentration smaller than 0.4M may also be used. In the case of spin coating, for example, at the time of spin coating, the light absorber solution may be adjusted so as not to remain on the surface of the porous metal oxide by increasing rpm. As a non-restrictive example, the light absorber solution may be adjusted so as not to remain on the surface of the porous supporter by adjusting the maximum rpm at the time of spin coating so as to be higher than 5000 rpm, more specifically, so as to be 6000 rpm or more.

The light absorber may be adjusted so as to be formed only in the porous supporter by decreasing the concentration of the light absorber solution. As a specific and non-restrictive example, a molar concentration of the light absorber of the light absorber solution may be less than 0.4M, but the concentration of the light absorber solution having a low concentration may be changed in consideration of the thickness and porosity of the porous metal oxide layer.

However, as described above, the solar cell having the composite layer and the light absorption structure body has significantly excellent power conversion efficiency, such that this solar cell is more preferable.

The forming of the hole transport layer may be performed after the forming of the light absorber, or selectively performing the plasma etching.

The forming of the hole transport layer may be performed by applying the solution containing an organic hole transport material (hereinafter, an organic hole transport solution) so as to cover the porous support layer provided with the light absorber, the composite layer, or the composite layer provided with the light absorption structure body and drying the applied solution. The application may be performed by spin coating. The organic hole transport material (hole transport layer) may have a thickness of 10 nm to 500 nm.

As a solvent used for forming the hole transport layer, any solvent may be used as long as it may dissolve the organic hole transport material and does not chemically react with the materials of the light absorber and the porous support layer. As an example, the solvent used for forming the hole transport layer may be a non-polar solvent. As a substantial example, the solvent may be one or at least two solvents selected from toluene, chloroform, chlorobenzene, dichlorobenzene, anisole, xylene, and hydrocarbon based solvents having 6 to 14 carbon atoms.

After the forming of the hole transport layer is performed, the forming of the second electrode may be performed. The forming of the second electrode may be performed by a general metal deposition method used in the semiconductor process. As an example, the second electrode may be formed using physical vapor deposition or chemical vapor deposition, and may be formed using thermal evaporation.

Hereinafter, Manufacturing Examples of the solar cell will be described in detail, but the Examples are provided only for assisting in the entire understanding of the present invention by way of example, and the present invention is not limited thereto.

### Preparation Example 1

Preparation of Light Absorber Solution

Methylammonium iodide (CH₃NH₃I) and lead diiodide (PbI₂) were dissolved at a molar ratio of 1:1 in gamma-butyrolactone and stirred at 60° C. for 12 hours, thereby preparing 40 wt % of methylammonium leadtriiodide (CH₃NH₃PbI₃) solution.

Methylammonium bromide (CH₃NH₃Br) and lead dibromide (PbBr₂) were dissolved at a molar ratio of 1:1 in dimethylformamide and stirred at 60° C. for 12 hours, thereby preparing 40 wt % of methylammonium leadtribromide (CH₃NH₃PbBr₃) solution.

These two solutions, the methylammonium leadtriiodide solution and the methylammonium leadtribromide solution were mixed so that a molar ratio of CH₃NH₃PbI₃(1-m) and CH₃NH₃PbBr₃(m) became 1(1-m):0(m), 0.99:0.01, 0.96:0.04, 0.95:0.05, 0.94:0.06, 0.9:0.1, 0.87:0.13, 0.85:0.15, 0.8:0.2, 0.75:0.25, 0.71:0.29, 0.7:0.3, 0.65:0.35, 0.62:0.38, 0.53:0.47, 0.5:0.5, 0.42:0.58, 0.29:0.71, 0.16:0.84, 0.1:0.9, or 0:1, thereby preparing methylammonium leadtriiodidebromide (CH₃NH₃Pb(I₁₋ₘBrₘ)₃) mixed solution (hereinafter, referred to as a “light absorber solution”).

### Preparation Example 2

Preparation of Light Absorber Solution

Methylammonium bromide (CH₃NH₃Br) and lead dibromide (PbBr₂) were dissolved at a molar ratio of 1:1 in dimethylformamide and stirred at 60° C. for 12 hours, thereby preparing 30 wt % of methylammonium leadtribromide (CH₃NH₃PbBr₃) solution.

Methylammonium chloride (CH₃NH₃Cl) and lead dichloride (PbCl₂) were dissolved at a molar ratio of 1:1 in dimethylformamide and stirred at 60° C. for 12 hours, thereby preparing 20 wt % of methylammonium leadtrichloride (CH₃NH₃PbCl₃) solution.

These two solutions, the methylammonium leadtribromide solution and the methylammonium leadtrichloride solution were mixed so that a molar ratio of CH₃NH₃PbCl₃(1-m) and CH₃NH₃PbBr₃(m) became 0(1-m):1(m), 0.3:0.7, or 0.6:0.4, thereby preparing a methylammonium leadtribromidechloride (CH₃NH₃Pb(Cl₁₋ₘBrₘ)₃) mixed solution (hereinafter, referred to as a “light absorber solution”).

### Example 1

After a glass substrate on which fluorine doped tin oxide (FTO; F-doped SnO₂, 8 ohms/cm², Pilkington, hereinafter, FTO substrate (first electrode)) was coated was cut at a size of 25×25 mm, end portions thereof were etched to partially remove FTO.

A dense structured TiO₂ thin film having a thickness of about 50 nm was manufactured by a spray pyrolysis method (SPM) on the cut and partially etched FTO substrate. The SPM was performed using a titanium acetylacetonate (TAA):EtOH (1:9 v/v %) solution, and the thickness was adjusted by repeating a process of spraying the solution onto the FTO substrate positioned on a hot plate maintained at 450° C. for 3 seconds and stopping for 10 seconds.

5 ml of an ethyl cellulose solution in which 10 wt % of ethyl cellulose was dissolved in ethyl alcohol was added to TiO₂ powder having an average particle size of 50 nm (preparing by hydrothermal treatment of an aqueous solution in which a titanium peroxo complex (1 wt % based on TiO₂) was dissolved at 250° C. for 12 hours) per 1 g of TiO₂, and 5 g of terpinol was added thereto per 1 g of TiO₂ and then mixed, followed by removing ethyl alcohol by a vacuum distillation method, thereby preparing a TiO₂ powder paste.

The prepared TiO₂ powder paste was coated onto the TiO₂ thin film on the FTO substrate by a screen printing method and heat-treated at 500° C. for 60 minutes. Then, after the heat-treated substrate was immersed in 30 mM TiCl₄ aqueous solution at 60° C. and left for about 30 minutes, the substrate was washed and dried using deionized water and ethanol, followed by heat-treatment at 500° C. for 30 minutes again, thereby manufacturing a porous support layer having a specific surface area of 40 m²/g and a thickness of 600 nm.

A light absorber solution having a composition corresponding to the case in which m was 0.01 in CH₃NH₃Pb(I₁₋ₘBrₘ)₃ prepared in Preparation Example 1 was spin coated onto the porous support layer at 2000 rpm for 60 seconds and at 3000 rpm for 60 seconds, and dried on a hot plate at 100° C. for 10 minutes, thereby forming the light absorber containing a solid-solution of CH₃NH₃Pb(I₁₋ₘBrₘ)₃ (m=0.01). At the time of preparing the light absorber, environmental conditions were maintained at a temperature of 25° C. and relative humidity of 25%.

A poly(triarylamine) (PTAA, EM index, Mw=17,500 g/mol) dissolved dichlorobenzene solution (15 mg (PTAA)/1 mL (dichlorobenzene)) was spin coated on the substrate on which the perovskite light absorber was coated at 2500 rpm for 60 seconds, thereby forming a hole transport layer.

Then, Au was vacuum deposited on an upper surface of the hole transport layer using high vacuum (5×10⁻⁶ torr or less) thermal evaporator, thereby forming an Au electrode (second electrode) having a thickness of about 70 nm.

In order to measure current-voltage characteristics of the manufactured solar cell, an ORIEL class A solar simulator (Newport, model 91195A) and a source-meter (Kethley, model 2420) were used. Power conversion efficiency was measured under 100 mW/cm² AM1.5 illumination conditions by covering an optical mask having an active area of 0.096 cm².

### Example 2

A solar cell was manufactured by the same method as in Example 1 except for forming a light absorber using the light absorber solution having a composition corresponding to the case in which m was 0.04 in CH₃NH₃Pb(I₁₋ₘBrₘ)₃ prepared in Preparation Example 1.

### Example 3

A solar cell was manufactured by the same method as in Example 1 except for forming a light absorber using the light absorber solution having a composition corresponding to the case in which m was 0.05 in CH₃NH₃Pb(I₁₋ₘBrₘ)₃ among the light absorber solutions prepared in Preparation Example 1.

### Example 4

A solar cell was manufactured by the same method as in Example 1 except for forming a light absorber using the light absorber solution having a composition corresponding to the case in which m was 0.1 in CH₃NH₃Pb(I₁₋ₘBrₘ)₃ among the light absorber solutions prepared in Preparation Example 1.

### Example 5

A solar cell was manufactured by the same method as in Example 1 except for forming a light absorber using the light absorber solution having a composition corresponding to the case in which m was 0.15 in CH₃NH₃Pb(I₁₋ₘBrₘ)₃ among the light absorber solutions prepared in Preparation Example 1.

### Example 6

A solar cell was manufactured by the same method as in Example 1 except for forming a light absorber using the light absorber solution having a composition corresponding to the case in which m was 0.2 in CH₃NH₃Pb(I₁₋ₘBrₘ)₃ among the light absorber solutions prepared in Preparation Example 1.

### Example 7

A solar cell was manufactured by the same method as in Example 1 except for forming a light absorber using the light absorber solution having a composition corresponding to the case in which m was 0.25 in CH₃NH₃Pb(I₁₋ₘBrₘ)₃ among the light absorber solutions prepared in Preparation Example 1.

### Example 8

A solar cell was manufactured by the same method as in Example 1 except for forming a light absorber using the light absorber solution having a composition corresponding to the case in which m was 0.30 in CH₃NH₃Pb(I₁₋ₘBrₘ)₃ among the light absorber solutions prepared in Preparation Example 1.

### Example 9

A solar cell was manufactured by the same method as in Example 1 except for forming a light absorber using the light absorber solution having a composition corresponding to the case in which m was 0.35 in CH₃NH₃Pb(I₁₋ₘBrₘ)₃ among the light absorber solutions prepared in Preparation Example 1.

### Example 10

A solar cell was manufactured by the same method as in Example 1 except for forming a light absorber using the light absorber solution having a composition corresponding to the case in which m was 0.38 in CH₃NH₃Pb(I₁₋ₘBrₘ)₃ among the light absorber solutions prepared in Preparation Example 1.

### Example 11

A solar cell was manufactured by the same method as in Example 1 except for forming a light absorber using the light absorber solution having a composition corresponding to the case in which m was 0.5 in CH₃NH₃Pb(I₁₋ₘBrₘ)₃ among the light absorber solutions prepared in Preparation Example 1.

### Example 12

A solar cell was manufactured by the same method as in Example 1 except for forming a light absorber using the light absorber solution having a composition corresponding to the case in which m was 0.58 in CH₃NH₃Pb(I₁₋ₘBrₘ)₃ among the light absorber solutions prepared in Preparation Example 1.

### Example 13

A solar cell was manufactured by the same method as in Example 1 except for forming a light absorber using the light absorber solution having a composition corresponding to the case in which m was 0.84 in CH₃NH₃Pb(I₁₋ₘBrₘ)₃ among the light absorber solutions prepared in Preparation Example 1.

### Example 14

A solar cell was manufactured by the same method as in Example 1 except for forming a light absorber using the light absorber solution having a composition corresponding to the case in which m was 0.9 in CH₃NH₃Pb(I₁₋ₘBrₘ)₃ among the light absorber solutions prepared in Preparation Example 1.

### Comparative Example 1

A solar cell was manufactured by the same method as in Example 1 except for forming a light absorber using the light absorber solution having a composition corresponding to the case in which m was 0 in CH₃NH₃Pb(I₁₋ₘBrₘ)₃ among the light absorber solutions prepared in Preparation Example 1.

### Comparative Example 2

A solar cell was manufactured by the same method as in Example 1 except for forming a light absorber using the light absorber solution having a composition corresponding to the case in which m was 1 in CH₃NH₃Pb(I₁₋ₘBrₘ)₃ among the light absorber solutions prepared in Preparation Example 1.

TABLE 1
Performance of Solar Cells Manufactured in Examples 1 to 14 and
Comparative Examples 1 and 2

| | | Short-Circuit | Open | | Power | Moisture |
|---|---|---|---|---|---|---|
| | | Current | circuit | | Conversion | Resis- |
| | | Density | voltage | Fill | Efficiency | tance |
| | m | (mA/cm²) | (V) | factor | (%) | (%) |
| Example 1 | 0.01 | 18.2 | 0.91 | 0.69 | 11.4 | 20 |
| Example 2 | 0.04 | 18.7 | 0.91 | 0.69 | 11.7 | 20 |
| Example 3 | 0.05 | 18.7 | 0.94 | 0.71 | 12.5 | 32 |
| Example 4 | 0.1 | 19.0 | 0.97 | 0.75 | 13.8 | 42 |
| Example 5 | 0.15 | 18.8 | 0.97 | 0.73 | 13.3 | 83 |
| Example 6 | 0.2 | 17.0 | 0.97 | 0.71 | 11.7 | 90 |
| Example 7 | 0.25 | 16.2 | 0.95 | 0.72 | 11.1 | 90 |
| Example 3 | 0.3 | 15.9 | 0.96 | 0.72 | 11.0 | 90 |
| Example 9 | 0.35 | 14.1 | 0.94 | 0.68 | 9.0 | 90 |
| Example 10 | 0.38 | 13.5 | 0.92 | 0.68 | 8.4 | 90 |
| Example 11 | 0.5 | 11.3 | 0.92 | 0.68 | 7.1 | 90 |
| Example 12 | 0.58 | 10.1 | 0.83 | 0.69 | 5.8 | 95 |
| Example 13 | 0.84 | 8.4 | 0.85 | 0.74 | 5.3 | 95 |
| Example 14 | 0.9 | 8.10 | 0.89 | 0.66 | 4.8 | 95 |
| Comparative | 0 | 17.5 | 0.88 | 0.65 | 10.0 | 15 |
| Example 1 | | | | | | |
| Comparative | 1 | 5.4 | 1.13 | 0.76 | 4.6 | 95 |
| Example 2 | | | | | | |

In Table 1, moisture resistance means a percentage of power conversion efficiency when the manufactured solar cell was left in a constant temperature and constant humidity state (25° C., RH 55%) for 100 hours to initial power conversion efficiency.

Initial performance of the solar cells manufactured in Examples 1 to 14 or Comparative Example 1 and 2 and changes in power conversion efficiency at the time of storing the solar cells in a thermo-hygrostat maintaining a relative humidity of 55% in the air and a temperature of 25° C. for 100 hours were observed. A ratio (moisture resistance) of final efficiency to the initial power conversion efficiency (as a fabricated state) depending on a storage time (in a constant temperature and constant humidity state) was shown in Table 1.

As shown in Table 1, it may be appreciated that in the case in which the light absorber was CH₃NH₃PbI₃ as in Comparative Example 1, the solar cell was significantly weak against moisture, such that power conversion efficiency was rapidly decreased. In the case of the solar cells containing the solid-solution according to the present invention, it may be appreciated that a decrease in efficiency by moisture was suppressed, and in the case of the solar cell manufactured in Example 4, it may be appreciated that final power conversion efficiency after storing the solar cell in the air at 25° C. and a relative humidity of 55% for 100 hours was maintained at 40% or more of the initial power conversion efficiency. Particularly, in the case of the solar cell manufactured in Example 5, it may be appreciated that final power conversion efficiency after storing the solar cell in the air at 25° C. and a relative humidity of 55% for 100 hours was maintained at 80% or more of the initial power conversion efficiency, and in the solar cells manufactured in Examples 6 to 14, efficiency was not substantially decreased.

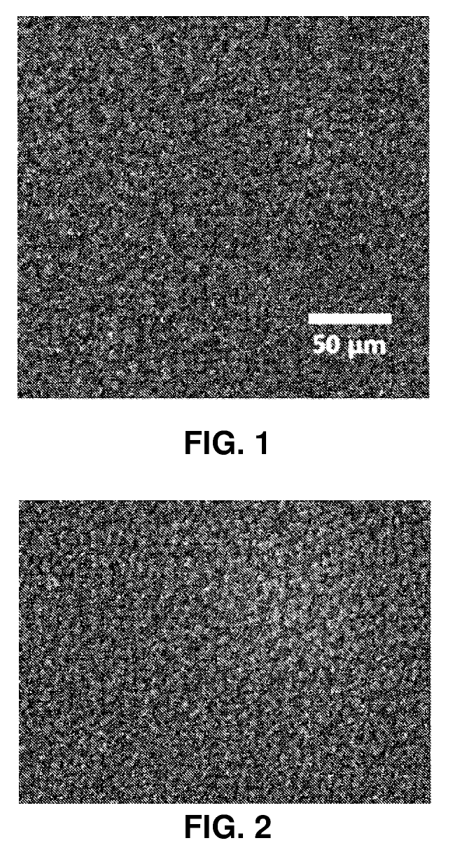

FIG. 1 is an optical photograph of a surface after forming the light absorber on the TiO₂ porous support layer on the FTO substrate in Example 4, and it may be appreciated that the light absorber formed uneven portions of nano-pillars on the porous support layer while filling the pores of the porous support layer.

In addition, as a result of observing structures and compositions of the light absorbers of the manufactured solar cells using an X-ray diffraction method and an energy dispersive spectrometer (EDS), it was confirmed that a single crystalline phase was manufactured, and it may be appreciated that all of the prepared light absorbers had a perovskite crystalline phase.

Further, in the cases of the solar cells according to the present invention it may be appreciated that all of the solar cells in Examples 1 to 8 containing bromine had 1.1 times or more, preferably up to 1.38 times the power conversion efficiency of the solar cell provided with the light absorber having a CH₃NH₃PbI₃ perovskite structure as in Comparative Example 1. In addition, it may be appreciated that light efficiency of the solar cells in the Examples was increased by 2 to 3 times or more as compared to the solar cell provided with the light absorber having a CH₃NH₃PbBr₃ perovskite structure as in Comparative Example 2. That is, it may be appreciated from the experimental results that the solar cells containing the solid-solution in which I ions in CH₃NH₃PbI₃ were partially substituted with Br ions as the light absorber had higher photoelectric conversion efficiency.

FIG. 2 is an optical photograph of a surface after forming the light absorber on the TiO₂ porous support layer on the FTO substrate in Example 2, and it may be appreciated that the light absorber formed uneven portions of nano-pillars on the porous support layer while filling the pores of the porous support layer. In addition, as a result of analyzing the structures of the prepared light absorbers depending on m using X-ray diffraction method, it was confirmed that as m was increased, a lattice size of the solid-solution was decreased, and a peak of a (110) plane of a tetragonal system was shifted to a high angle and a phase transformation phenomenon that peaks of (002) and (110) planes of the tetragonal system were merged into a single peak of a (100) plane of a cubic system was confirmed.

### Preparation Example 3

After a glass substrate on which fluorine doped tin oxide (FTO; F-doped SnO₂, 8 ohms/cm², Pilkington, hereinafter, FTO substrate (first electrode)) was coated was cut at a size of 25×25 mm, end portions thereof were etched to partially remove FTO.

A dense structured TiO₂ thin film having a thickness of about 50 nm was manufactured by a spray pyrolysis method (SPM) on the cut and partially etched FTO substrate. The SPM was performed using a titanium acetylacetonate (TAA):EtOH (1:9 v/v %) solution, and the thickness was adjusted by repeating a process of spraying the solution onto the FTO substrate positioned on a hot plate maintained at 450° C. for 3 seconds and stopping for 10 seconds.

5 ml of an ethyl cellulose solution in which 10 wt % of ethyl cellulose was dissolved in ethyl alcohol was added to TiO₂ powder having an average particle size of 50 nm (preparing by hydrothermal treatment of an aqueous solution in which a titanium peroxo complex (1 wt % based on TiO₂) was dissolved at 250° C. for 12 hours) per 1 g of TiO₂, and 5 g of terpinol was added thereto per 1 g of TiO₂ and then mixed, followed by removing ethyl alcohol by a vacuum distillation method, thereby preparing a TiO₂ powder paste.

The prepared TiO₂ powder paste was coated onto the TiO₂ thin film on the FTO substrate by a screen printing method and heat-treated at 500° C. for 60 minutes. Then, after the heat-treated substrate was immersed in 30 mM TiCl₄ aqueous solution at 60° C. and left for about 30 minutes, the substrate was washed and dried using deionized water and ethanol, followed by heat-treatment at 500° C. for 30 minutes, thereby manufacturing a porous support layer having a specific surface area of 40 m²/g and a thickness of 600 nm.

The light absorber solution (m was 0, 0.06, 0.13, 0.20, 0.29, 0.38, 0.47, 0.58, 0.71, 0.84, or 1.0) prepared in Preparation Example 1 was spin coated on the porous support layer at 2000 rpm for 60 seconds and at 3000 rpm for 60 seconds and dried on a hot plate of 100° C. for 10 minutes, thereby forming a light absorber containing a solid-solution of CH₃NH₃Pb(I₁₋ₘBrₘ)₃. At the time of preparing the light absorber, environmental conditions were maintained at a temperature of 25° C. and relative humidity of 25%.

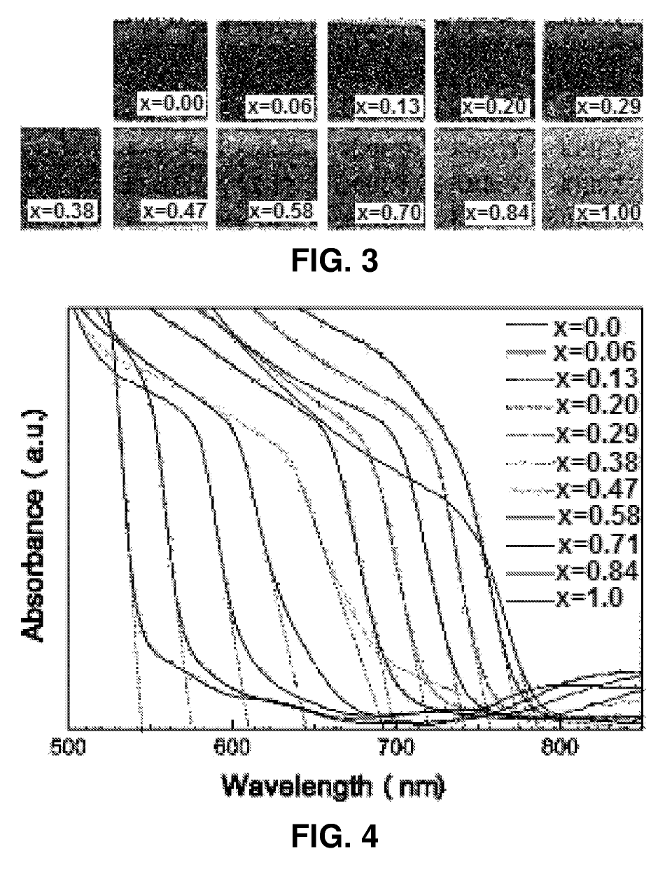

FIG. 3 is optical photographs of the substrates provided with the light absorbers, and “x=” shown in a lower end of each of the photographs means m of the molar ratio (1-m:m) of CH₃NH₃PbI₃ and CH₃NH₃PbBr₃ in the light absorber solution used for forming the light absorber. In addition, band gap energy of the solid-solution depending on m of the molar ratio (1-m:m) of CH₃NH₃PbI₃ and CH₃NH₃PbBr₃ in the light absorber solution was measured and shown in Table 2.

TABLE 2
Band Gap Energy of Solid-solution Depending on m of CH₃NH₃Pb (I₁-ₘBrₘ)₃

| m | 0.0 | 0.06 | 0.13 | 0.20 | 0.29 | 0.38 | 0.47 | 0.58 | 0.71 | 0.84 | 1.00 |
|---|---|---|---|---|---|---|---|---|---|---|---|
| Band gap | 1.58 | 1.60 | 1.64 | 1.67 | 1.72 | 1.77 | 1.79 | 1.93 | 2.03 | 2.16 | 2.28 |
| (eV) | | | | | | | | | | | |

As shown in FIG. 3 and Table 2, it may be appreciated that as a content of Br in the solid-solution was increased, the band gap energy was increased, such that a color of the substrate coated with the light absorber was changed from dark-red (x=0.06 or so) into red (x=0.20 or so), and from orange (x=−0.71 or so) into light orange (yellowish orange, x=0.84 or so). Therefore, it may be appreciated that the color of the solar cell may be adjusted by controlling a ratio of a halogen ion in the solid-solution.

FIG. 4 is a view illustrating a measurement result of UV-VIS absorbance spectrum depending on m of a CH₃NH₃Pb(I₁₋ₘBrₘ)₃ light absorber formed in the TiO₂ porous support layer on the FTO substrate. As shown in FIG. 4, it may be appreciated that in the case of the solar cell in which the solid-solution phase light absorber was formed, the solar cell has an absorption wavelength between an absorption wave length when m was 0, that is, an absorption wavelength of the CH₃NH₃PbI₃ light absorber and an absorption wavelength when m was 1, that is, an absorption wavelength of the CH₃NH₃PbBr₃ light absorber, and as m was decreased, the absorption wavelength was increased.

### Preparation Example 4

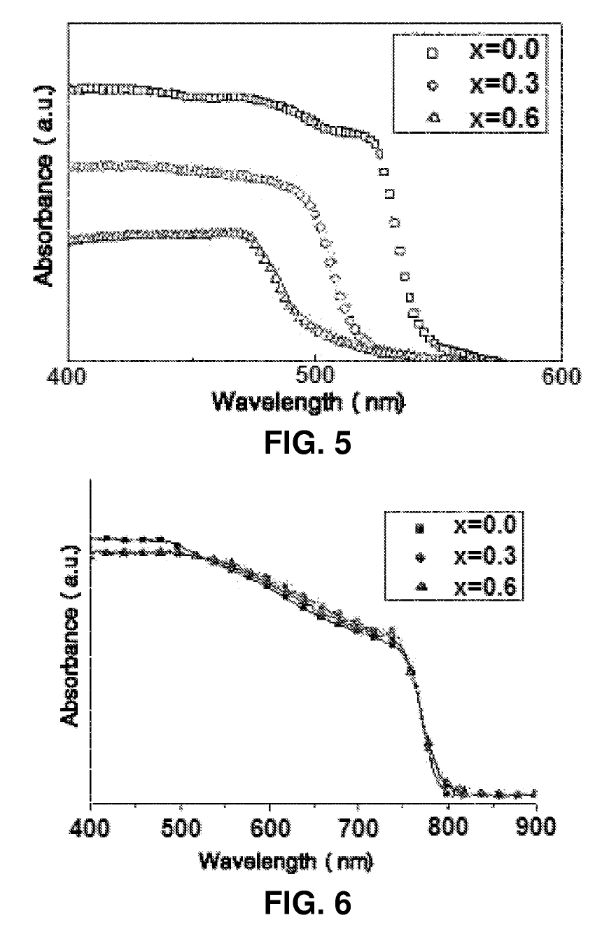

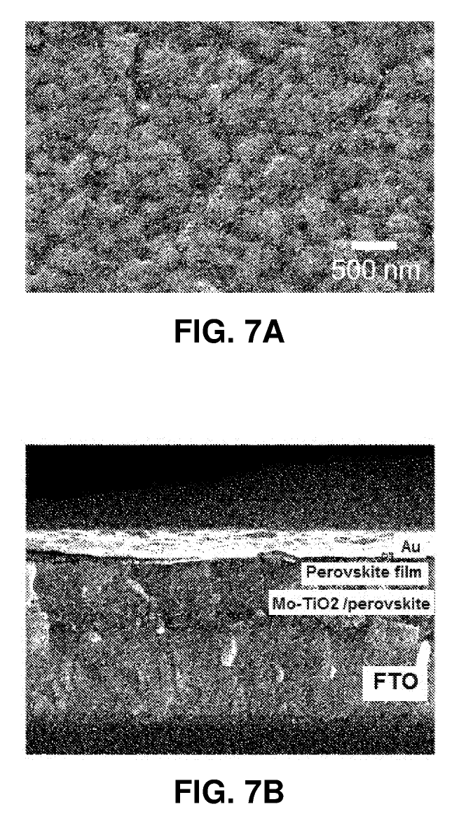

A light absorber was coated on the TiO₂ porous support layer by the same method as in Preparation Example 3 except for using the light absorber solution prepared in Preparation Example 2 instead of the light absorber solution of Preparation Example 1 in Preparation Example 3. FIG. 5 is a view illustrating a measurement result of UV-VIS absorbance spectrum depending on m of a CH₃NH₃Pb(CI₁₋ₘBrₘ)₃ light active layer formed in the TiO₂ porous support layer on the FTO substrate. In this case, ‘x=’ of FIG. 5 means 1-m of CH₃NH₃Pb(Cl₁₋ₘBrₘ)₃. As shown in FIG. 5, it may be appreciated that as a content of Cl was increased, an absorption spectrum moved toward a short wavelength, and band gap of the light absorber was increased.

### Comparative Example 3

Preparation of Light Absorber Solution

Methylammonium iodide (CH₃NH₃I) and lead diiodide (PbI₂) were dissolved at a molar ratio of 1:1 in gamma-butyrolactone and stirred at 60° C. for 12 hours, thereby preparing 40 wt % of methylammonium leadtriiodide (CH₃NH₃PbI₃) solution.

Methylammonium chloride (CH₃NH₃Cl) and lead dichloride (PbCl₂) were dissolved at a molar ratio of 1:1 in dimethylformamide and stirred at 60° C. for 12 hours, thereby preparing 20 wt % of methylammonium leadtrichloride (CH₃NH₃PbCl₃) solution.

These two solutions, the methylammonium leadtriiodide solution and the methylammonium leadtrichloride solution were mixed so that a molar ratio of CH₃NH₃Pbl₃(1-m) and CH₃NH₃PbCl₃(m) became 1(1-m):0(m), 0.7:0.3, or 0.4:0.6, thereby preparing a methylammonium leadtriiodidechloride (CH₃NH₃Pb(l₁₋ₘClₘ)₃) mixed solution (hereinafter, referred to as a “light absorber solution”).

A light absorber was coated on the TiO₂ porous support layer by the same method as in Example 1 except for using the prepared methylammonium leadtriiodidechloride (CH₃NH₃Pb(l₁₋ₘClₘ)₃) mixed solution instead of the light absorber solution of Preparation Example 1 in Example 1. FIG. 6 is a view illustrating a measurement result of UV-VIS absorbance spectrum depending on m of a CH₃NH₃Pb(I₁₋ₘClₘ)₃ light active layer formed in the TiO₂ porous support layer on the FTO substrate. In this case, ‘x=’ of FIG. 6 means m of CH₃NH₃Pb(l₁₋ₘClₘ)₃. As shown in FIG. 6, it may be appreciated that even though a content of Cl was increased, a light absorption spectrum was not changed.

### Example 15

Methylammonium iodide (CH₃NH₃I), lead diiodide (PbI₂), methylammonium bromide (CH₃NH₃Br), and leaddibromide (PbBr₂) were dissolved in a mixed solution in which gamma butyrolactone and dimethylsulfoxide were mixed at a volume ratio of 8:2 (gamma butyrolactone:dimethylsulfoxide) so that m was 0.1 and a concentration became 0.96M based on Chemical Formula CH₃NH₃Pb(I₁₋ₘBrₘ)₃ and stirred at 60° C. for 12 hours, thereby preparing a 0.96M CH₃NH₃Pb(I₁₋ₘBrₘ)₃ light absorber solution (m=0.1).

A porous electrode provided with a porous electron carrier manufactured by a method according to Example 1 was used, and the prepared light absorber solution (total volume of 1 ml, at least 700% based on the total pore volumes of the porous electron carrier) was applied onto (injected into) a rotational center on the porous electrode having a thickness of 300 nm at a time and spin coating was initiated at 3000 rpm. At a point in time at which a spin coating time was 50 seconds, 1 mL of toluene, which is a non-solvent, was applied again onto (injected into) the rotational center of the spinning porous electrode at a time, and then spin coating was further performed for 5 seconds. After performing the spin coating, the drying was performed at 100° C. under normal pressure for 30 minutes, thereby forming a perovskite light absorber. At the time of preparing the light absorber, environmental conditions were maintained at a temperature of 25° C. and relative humidity of 25%. In addition, PTAA and Au were deposited by the method of Example 1, and efficiency of a solar cell was measured.

As a result of observing a cross section and a surface of the solar cell manufactured in Example 15 after forming the light absorber using a scanning electron microscope, it was confirmed that a light absorption structure body having a thickness of 300 nm, which was a film form of the light absorber, rather than a pillar-shaped light absorption structure body was manufactured. It was confirmed that in the case in which the light absorber film covering the porous supporter was manufactured, a short-circuit current density was 22 mA/cm², an open circuit voltage was 1.08 V, a fill factor was 0.75, and the solar cell had power conversion efficiency of 17.8%. Therefore, it may be appreciated that in the case of the light absorption structure body having a film form, power conversion efficiency was significantly improved.

In addition, even in the case of the light absorption structure body having the film form, a change in band gap energy similar in Table 2 may be confirmed depending on m of the ratio of I(1-m) and Br(m). In addition, it may be confirmed that light absorption structure body had significantly improved power conversion efficiency as compared to the light absorption structure body having the pillar structure, and depending on m, the solar cell had more excellent power conversion efficiency when m was less than 0.35. Further, it was confirmed that depending on m, the light absorption structure body had moisture resistance similar to or more excellent than that of the light absorption structure body having the pillar structure.

Hereinabove, although the present invention is described by specific matters, exemplary embodiments, and drawings, they are provided only for assisting in the entire understanding of the present invention. Therefore, the present invention is not limited to the exemplary embodiments. Various modifications and changes may be made by those skilled in the art to which the present invention pertains from this description.

Therefore, the spirit of the present invention should not be limited to the above-described embodiments, and the following claims as well as all modified equally or equivalently to the claims are intended to fall within the scope and spirit of the invention.

1. A manufacturing method of a solar cell comprising:
a) preparing a mixed solution by mixing and dissolving one organic-metal halide satisfying Chemical Formula 1 and another organic-metal halide satisfying Chemical Formula 2;
b) manufacturing a porous support layer on a first electrode;
c) applying the mixed solution of step a) onto the porous support layer, and drying the mixed solution to form a light absorber containing a solid solution having a perovskite structure and satisfying Chemical Formula 3; and
d) applying and drying a hole transport solution in which an organic hole transport material is dissolved to form a hole transport layer;
AMX₃ (Chemical Formula 1)
(in Chemical Formula 1, A is a monovalent organic ammonium ion, a monovalent ammonium ion, or Cs⁺, M is a divalent metal ion, and X is Br⁻), and
A′M′X′₃ (Chemical Formula 2)
(in Chemical Formula 2, A′ is a monovalent organic ammonium ion, a monovalent ammonium ion, or Cs⁺, M′ is a divalent metal ion, and X′ is I⁻ or Cl⁻)
A″M′(X₁₍₁₋ₘ₎X₂₍ₘ₎)₃ (Chemical Formula 3)
(in Chemical Formula 3, A″ is a monovalent organic ammonium ion, a monovalent ammonium ion, or Cs⁺, M″ is a divalent metal ion, X₁ is I⁻ or Cl⁻, X₂ is Br⁻, and m is a real number satisfying 0<m<1).

2. The method of claim 1, wherein in Chemical Formula 3, m is a real number satisfying 0<m≤0.5.

3. The method of claim 1, wherein when the solar cell was left in a constant temperature and constant humidity state (25° C., RH 55%) for 100 hours, power conversion efficiency thereof is maintained at 18% or more of initial power conversion efficiency.

4. The method of claim 1, wherein in Chemical Formula 3, m is a real number satisfying 0.01≤m≤0.3.

5. The method of claim 1, wherein power conversion efficiency of the solar cell is 11.0% or more.
